(19) United States
(12) Patent Application Publication
(10) Pub. No.: US 2025/0336728 A1
(43) Pub. Date: Oct. 30, 2025

(54) WAFER, INSPECTION METHOD FOR LIGHT EMITTING ELEMENT, MANUFACTURING METHOD FOR DISPLAY DEVICE, AND INSPECTION DEVICE FOR LIGHT EMITTING ELEMENT

(71) Applicant: Samsung Display Co., LTD., Yongin-si (KR)

(72) Inventors: Su Mi MOON, Yongin-si (KR); Jin Seok PARK, Yongin-si (KR); Moon Jung AN, Yongin-si (KR); Chae Woo CHUNG, Yongin-si (KR)

(21) Appl. No.: 19/020,464

(22) Filed: Jan. 14, 2025

(30) Foreign Application Priority Data
Apr. 26, 2024 (KR) 10-2024-0055950

(51) Int. Cl. H01L 21/66; H10H 20/812; H10H 29/01; H10H 29/39; H10H 29/49; H10H 29/80; H10H 29/856

(52) U.S. Cl. CPC H01L 22/10; H10H 29/012; H10H 29/0364; H10H 29/39; H10H 29/49; H10H 29/8321; H10H 29/856; H10H 20/812

(57) ABSTRACT

A wafer includes: a substrate; a plurality of light emitting elements on the substrate, each of the plurality of light emitting elements includes a semiconductor stack, a first contact electrode, and a second contact electrode; a plurality of pin pads on the substrate and including a semiconductor stack; and a plurality of connectors connecting different pin pads to each of the first contact electrode and the second contact electrode of a light emitting element from among the plurality of light emitting elements.

### CROSS-REFERENCE TO RELATED APPLICATION

This application claims priority to and the benefit of Korean Patent Application No. 10-2024-0055950, filed on Apr. 26, 2024, in the Korean Intellectual Property Office, the entire disclosure of which is incorporated by reference herein.

### BACKGROUND

### 1. Field

The present disclosure relates to a wafer, an inspection method of a light emitting element, a manufacturing method of a display device, and an inspection device for the light emitting element.

### 2. Description of the Related Art

As the information society develops, the demand for display devices for displaying images is increasing in various forms. The display device may be a flat panel display such as a liquid crystal display, a field emission display, a light emitting display, and/or the like.

The light emitting display device may include an organic light emitting display device including an organic light emitting diode (OLED) element as a light emitting element, and a micro light emitting display device including a micro light emitting diode element (hereinafter referred to as a micro light emitting diode element) as a light emitting element. Because the micro light emitting diode element is made of inorganic materials, it has the advantage of having less deterioration issues and a longer lifespan compared to an organic light emitting diode (OLED) element.

In a display device manufactured through a process of bonding a micro light emitting element to a display panel, defect inspection of the micro light emitting element is performed after the display device process is completed. If a defect in the micro light emitting element is discovered after the display device process is completed, the conventional lighting inspection method has the problem of reduced process efficiency and consequent decrease in productivity because it is not easy to replace a defective micro light emitting element with a good quality light emitting element.

Aspects and features of embodiments of the present disclosure are to provide a wafer, an inspection method, and the like that may inspect defects in light emitting elements on a wafer.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a wafer includes: a substrate; a plurality of light emitting elements on the substrate, each of the plurality of light emitting elements includes a semiconductor stack, a first contact electrode, and a second contact electrode; a plurality of pin pads on the substrate and including a semiconductor stack; and a plurality of connectors connecting different pin pads to each of the first contact electrode and the second contact electrode of a light emitting element from among the plurality of light emitting elements.

The semiconductor stack includes a third semiconductor layer, a second semiconductor layer, an active layer, and a first semiconductor layer sequentially stacked.

The plurality of pin pads includes a first pin pad and a second pin pad, wherein a connector from among the plurality of connectors includes a first connector connecting the first contact electrode and the first pin pad and a second connector connecting the second contact electrode and the second pin pad.

The first pin pad, the light emitting element, and the second pin pad are aligned with each other in a first direction.

The first pin pad and the second pin pad are not aligned in a first direction, and the light emitting element is not aligned with the first pin pad and the second pin pad.

The plurality of pin pads further includes a contact pad on the semiconductor stack, wherein the contact pad, the first contact electrode, the second contact electrode, and the plurality of connectors are formed integrally with each other.

The plurality of light emitting elements is arranged along a first direction and a second direction, wherein the plurality of pin pads is arranged alternately with the plurality of light emitting elements along the second direction, wherein a pin pad located between a first light emitting element and a second light emitting element in the second direction is connected to the second contact electrode of the first light emitting element and is connected to the first contact electrode of the second light emitting element.

The semiconductor stack of the light emitting element includes a concave groove exposing a second semiconductor layer of the semiconductor stack in an area overlapping the second contact electrode, wherein the second contact electrode is electrically connected to the second semiconductor layer exposed by the concave groove, and wherein the first contact electrode is electrically connected to a first semiconductor layer of the semiconductor stack.

In one or more embodiments, display device includes: a substrate; a pixel electrode and a common electrode on the substrate and spaced from each other; a light emitting element on the pixel electrode and the common electrode; a first contact electrode on the light emitting element and the pixel electrode, and a second contact electrode on the light emitting element and the common electrode; and wherein the light emitting element includes: a semiconductor layer stack; a protective layer around all sides of the semiconductor layer stack except one side; a reflective layer around the semiconductor layer stack on the protective layer; a first tip extending from the first contact electrode and protruding outward perpendicular to a side surface of the semiconductor layer stack; and a second tip extending from the second contact electrode and protruding outward perpendicular to a side surface of the semiconductor layer stack.

The display device further includes a first connection electrode electrically connecting the first contact electrode and the pixel electrode, and a second connection electrode electrically connecting the second contact electrode and the common electrode.

The reflective layer further includes a first reflective layer between the first contact electrode and the protective layer and a second reflective layer between the second contact electrode and the protective layer, and wherein the first reflective layer and the second reflective layer are electrically short-circuited.

The semiconductor layer stack includes a concave groove exposing a second semiconductor layer of the semiconductor layer stack in an area overlapping the second contact electrode, wherein the second contact electrode is electrically connected to the second semiconductor layer exposed by the concave groove, and wherein the first contact electrode is electrically connected to a first semiconductor layer of the semiconductor layer stack.

In one or more embodiments, an inspection method of light emitting element, the method includes: forming a plurality of semiconductor stacks by stacking and etching a plurality of semiconductor material layers stacked on a substrate; forming a protective layer covering a portion of top and side surfaces of the plurality of semiconductor stacks; forming a contact electrode or a contact pad on the protective layer to form a light emitting element or a pin pad, wherein the pin pad is electrically connected to the contact electrode through a connector; and contacting a first probe and a second probe to each of a first pin pad and a second pin pad of the pin pad connected to the contact electrode of the light emitting element and applying test supply power.

In the forming the contact electrode or the contact pad on the protective layer to form the light emitting element or the pin pad, the pin pad is electrically connected to the contact electrode through the connector, wherein the light emitting element is formed by forming a first contact electrode and a second contact electrode on the protective layer of a first semiconductor stack of the plurality of semiconductor stacks, wherein the first pin pad is formed by forming the contact pad on the protective layer of a second semiconductor stack of the plurality of semiconductor stacks; wherein the second pin pad is formed by forming the contact pad on the protective layer of a third semiconductor stack of the plurality of semiconductor stacks; wherein the connector includes a first connector and a second connector, wherein the method further includes forming the first connector connecting the first contact electrode and the first pin pad and the second connector connecting the first contact electrode and the second pin pad.

The first semiconductor stack, the second semiconductor stack, and the third semiconductor stack are arranged with each other along a straight line in a first direction.

The method further includes acquiring an image of light emitted from the light emitting element to which the test supply power is applied; and determining characteristics of the light emitting element by a control portion comparing the acquired image with a reference image.

In one or more embodiments, a manufacturing method of a display device including a plurality of light emitting elements, the method includes: forming a plurality of semiconductor stacks by stacking and etching a plurality of semiconductor material layers stacked on a wafer substrate; forming a protective layer covering a portion of top and side surfaces of the plurality of semiconductor stacks; forming a contact electrode or a contact pad on the protective layer to form a light emitting element of the plurality of light emitting elements or a pin pad, wherein the pin pad is electrically connected to the contact electrode through a connector; contacting a first probe and a second probe to each of a first pin pad and a second pin pad of the pin pad connected to the contact electrode of the light emitting element and inspecting the light emitting element; and transferring the plurality of light emitting elements to a circuit board.

In the forming the contact electrode or the contact pad on the protective layer to form the light emitting element or the pin pad, the pin pad is electrically connected to the contact electrode through the connector including a first connector and a second connector, the contact electrode including a first contact electrode and a second contact electrode, wherein the light emitting element is formed by forming the first contact electrode and the second contact electrode on the protective layer of a first semiconductor stack of the plurality of semiconductor stacks, wherein the first pin pad is formed by forming the contact pad on the protective layer of a second semiconductor stack of the plurality of semiconductor stacks, wherein the second pin pad is formed by forming the contact pad on the protective layer of a third semiconductor stack of the plurality of semiconductor stacks, wherein the first connector connecting the first contact electrode and the first pin pad, and the second connector connecting the first contact electrode and the second pin pad.

The contacting the first probe and the second probe to each of the first pin pad and the second pin pad connected to the contact electrode of the light emitting element and inspecting the light emitting element includes: contacting the first probe and the second probe to each of the first pin pad and the second pin pad connected to the contact electrode of the light emitting element and applying test supply power; acquiring an image of light emitted from the light emitting element to which the test supply power is applied; and determining characteristics of the light emitting element by a control portion comparing the acquired image with a reference image.

The circuit board includes a plurality of pixel circuit portions, a pixel electrode connected to each of the pixel circuit portion, and a common electrode spaced from the pixel electrode, wherein the light emitting element includes a first contact electrode and a second contact electrode, wherein after the plurality of light emitting elements is transferred to the circuit board, the method further includes: forming a first connection electrode connecting the first contact electrode and the pixel electrode and a second connection electrode connecting the second contact electrode and the common electrode.

The display device and its manufacturing method according to one or more embodiments, an element characteristic of a flip-type light emitting element or a lateral-type light emitting element may be detected on a wafer.

However, the effects, aspects, and features of the present disclosure are not limited to the aforementioned effects, aspects, and features, and various other effects, aspects, and features are included in the present disclosure.

### BRIEF DESCRIPTION OF THE DRAWINGS

These and/or other aspects of embodiments of the present disclosure will become apparent and more readily appreciated from the following description of the embodiments, taken in conjunction with the accompanying drawings in which:

FIG. 1 is a perspective view of a display device according to one or more embodiments.

FIG. 2 is a layout view of the display device according to one or more embodiments.

FIG. 3 is a block diagram of the display device according to one or more embodiments.

FIG. 4 is an equivalent circuit diagram of a subpixel according to one or more embodiments.

FIG. 5 is a layout diagram illustrating pixels of a display area according to one or more embodiments.

FIG. 6 is a cross-sectional view illustrating an example cross-section of one display panel corresponding to the lines I1-I1′ in FIG. 5.

FIG. 7 is a cross-sectional view illustrating one example of an area A of FIG. 6 in detail.

FIG. 8 is a plan view illustrating the light emitting element of FIG. 7 in detail.

FIGS. 9 and 10 are plan views illustrating details of a light emitting element according to one or more embodiments.

FIG. 11 is a layout diagram illustrating pixels of a display area according to one or more embodiments.

FIG. 12 is a cross-sectional view illustrating an example of a cross-section of a display panel corresponding to the lines I1-I1′, I2-I2′, and I3-I3′ in FIG. 11.

FIG. 13 is a cross-sectional view illustrating one example of an area B in FIG. 12 in detail.

FIG. 14 is a layout diagram illustrating light emitting elements and pin pads on a wafer according to one or more embodiments.

FIG. 15 is a layout view illustrating one example of an area C in FIG. 14 in detail.

FIG. 16 is a plan view illustrating one test block of FIG. 14 in detail.

FIG. 17 is a cross-sectional view illustrating the test block of FIG. 16 in detail.

FIGS. 18 and 19 are layout views illustrating one example of the area C in FIG. 14 in detail according to one or more embodiments.

FIG. 20 is a schematic diagram illustrating a light emitting element inspection device according to one or more embodiments.

FIG. 21 is a flowchart illustrating a method of manufacturing a display device according to one or more embodiments.

FIG. 22 is a flowchart illustrating a method of manufacturing another wafer according to one or more embodiments.

FIGS. 23-30 are diagrams for illustrating a method of manufacturing a wafer and a method of transferring a light emitting element according to one or more embodiments.

FIG. 31 is an example view of a smart watch including a display device according to one or more embodiments;

FIGS. 32 and 33 are example views of a virtual reality (VR) device including a display device according to one or more embodiments;

FIG. 34 is an example view of a VR device including a display device according to one or more embodiments;

FIG. 35 is an example view illustrating a vehicle instrument cluster and center fascia including display devices according to one or more embodiments; and

FIG. 36 is an example view of a transparent display device including a display device according to one or more embodiments.

### DETAILED DESCRIPTION

Embodiments will now be described more fully hereinafter with reference to the accompanying drawings. Embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not necessary for one of ordinary skill in the art to fully understand the present disclosure may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

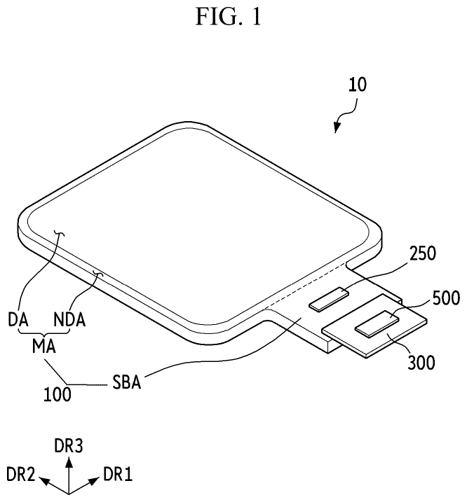

FIG. 1 is a perspective view of a display device 10 according to one or more embodiments.

Referring to FIG. 1, the display device 10 is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and/or Internet of things (IoT) devices.

The display device 10 may be a light emitting display such as an organic light emitting display using an organic light emitting diode (OLED), a quantum dot light emitting display including a quantum dot light emitting layer, an inorganic light emitting display including an inorganic semiconductor, or a micro-or nano-light emitting display using a micro-or nano-light emitting diode (LED). A case where the display device 10 is a micro-or nano-light emitting display will be mainly described below, but the present disclosure is not limited thereto. For ease of description, a micro-or nano-LED will be referred to as a light emitting element.

The display device 10 includes a display panel 100, a display driving circuit 250, a circuit board 300, and a power supply unit 500.

The display panel 100 may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded to have a suitable curvature (e.g., a predetermined curvature) or may be right-angled. The planar shape of the display panel 100 is not limited to a quadrangular shape but may also be other polygonal shapes, a circular shape, and/or an elliptical shape. The display panel 100 may be formed flat, but the present disclosure is not limited thereto. For example, the display panel 100 may include a curved portion formed at left and right ends and having a constant or varying curvature. In addition, the display panel 100 may be formed to be flexible so that it can be curved, bent, folded, and/or rolled.

A substrate SUB of the display panel 100 may include a main area MA and a sub-area SBA.

The main area MA may include a display area DA that displays an image and a non-display area NDA disposed around the display area DA along an edge or a periphery of the display area DA. The display area DA may include a plurality of pixels that display an image. Each of the pixels may include a plurality of subpixels. For example, each of the pixels may include a first subpixel that emits light of a first color, a second subpixel that emits light of a second color, and a third subpixel that emits light of a third color, but the present disclosure is not limited thereto.

The sub-area SBA may protrude from a side of the main area MA in the second direction DR2. Although the sub-area SBA is unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached onto the display panel 100 using a chip on glass (COG) method, a chip on plastic (COP) method, and/or an ultrasonic bonding method. However, the present disclosure is not limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film (COF).

The power supply unit 500 may generate a plurality of panel driving voltages according to a power supply voltage from the outside. The power supply unit 500 may be formed as an integrated circuit (IC) and attached onto the circuit board 300 using a COF method.

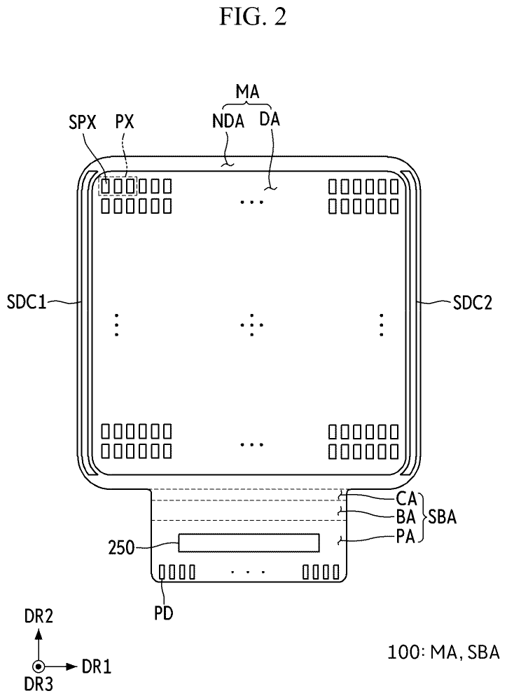

FIG. 2 is a layout view of the display device 10 according to one or more embodiments. FIG. 2 illustrates a state in which the sub-area SBA is unfolded without being bent.

Referring to FIG. 2, the display panel 100 may include the main area MA and the sub-area SBA.

The main area MA may include the display area DA that displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express a white gray level.

The non-display area NDA may neighbor the display area DA. The non-display area NDA may be an area outside the display area DA. The non-display area NDA may be around (e.g., may surround) the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, the present disclosure is not limited thereto.

Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

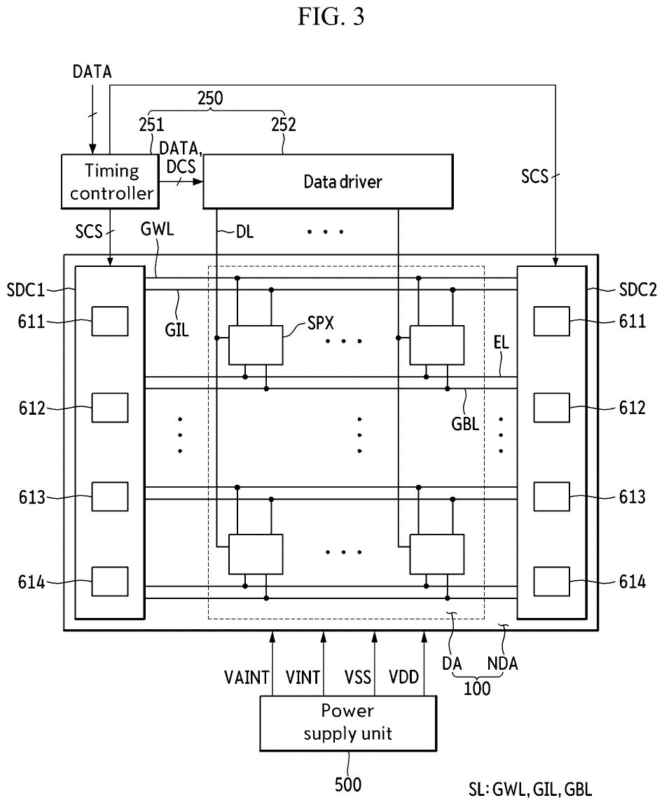

FIG. 3 is a block diagram of the display device 10 according to one or more embodiments.

Referring to FIG. 3, the display area DA includes a plurality of pixels PX, a plurality of scan lines SL, a plurality of emission control lines EL, and a plurality of data lines DL.

The pixels PX may be arranged in a matrix form along the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL include a plurality of write scan lines GWL, a plurality of initialization scan lines GIL, and a plurality of bias scan lines GBL.

Each of the subpixels SPX may be connected to one of the write scan lines GWL, one of the control scan lines GCL, one of the initialization scan lines GIL, one of the bias scan lines GBL, one of the emission control lines EL, and one of the data lines DL. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission signal output unit 614. Each of the write scan signal output unit 611, the initialization scan signal output unit 612, the bias scan signal output unit 613, and the emission signal output unit 614 may receive a scan timing control signal SCS from a timing controller 251. The write scan signal output unit 611 may generate write scan signals according to the scan timing control signal SCS of the timing controller 251 and sequentially output the write scan signals to the write scan lines GWL. The initialization scan signal output unit 612 may generate initialization scan signals according to the scan timing control signal SCS and sequentially output the initialization scan signals to the initialization scan lines GIL. The bias scan signal output unit 613 may generate bias scan signals according to the scan timing control signal SCS and sequentially output the bias scan signals to the bias scan lines GBL. The emission signal output unit 614 may generate emission control signals according to the scan timing control signal SCS and sequentially output the emission control signals to the emission control lines EL. In one or more embodiments, a control scan signal output unit of each of the first scan driver SDC1 and the second scan driver SDC2 may generate control scan signals according to the scan timing control signal SCS and sequentially output the control scan signals to the control scan lines.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from the outside. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage from the outside. For example, the power supply unit 500 may generate a first driving voltage VDD, a second driving voltage VSS, a third driving voltage VINT, and a fourth driving voltage VAINT and supply them to the display panel 100.

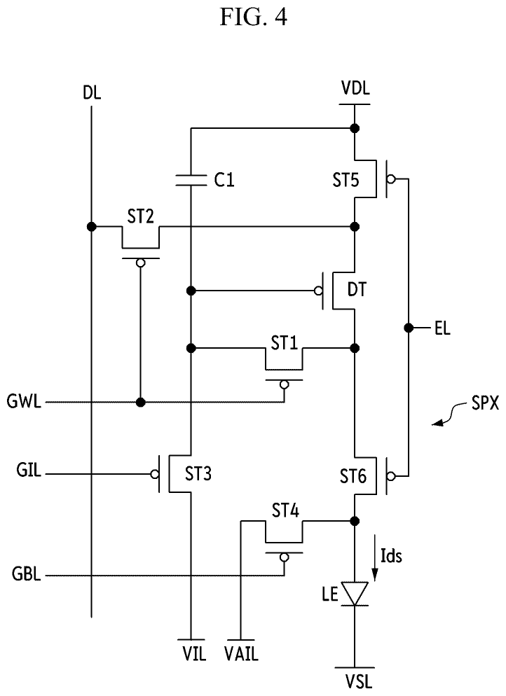

FIG. 4 is an equivalent circuit diagram of a subpixel SPX according to one or more embodiments.

Referring to FIG. 4, the subpixel SPX according to one or more embodiments may be connected to scan lines GWL, GIL, and GBL, an emission control line EL, and a data line DL. For example, the subpixel SPX may be connected to a write scan line GWL, an initialization scan line GIL, a bias scan line GBL, the emission line EL, and the data line DL.

The subpixel SPX according to the embodiment includes a driving transistor DT, switch elements, a capacitor C1, and a light emitting element LE. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode according to a data voltage applied to the gate electrode.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a first electrode of the fourth transistor ST4 and a second electrode of the sixth transistor ST6, and a cathode may be connected to a second power line VSL to which a second power supply voltage VSS is applied.

The capacitor C1 is formed between the gate electrode of the driving transistor DT and a first power line VDL to which a first power supply voltage VDD is applied. The first power supply voltage VDD may be at a higher level than the second power supply voltage VSS. One electrode of the capacitor C1 may be connected to the gate electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and the gate electrodes of the fifth and sixth transistors ST5 and ST6 may be connected to the emission line EL. Because the first through sixth transistors ST1 through ST6 are formed as p-type MOSFETs, they may be turned on when a scan signal of a gate-low voltage and an emission control signal of gate-low voltage are transmitted to the initialization scan line GIL, the write scan line GWL, the bias scan line GBL, and the emission line EL. One electrode of the third transistor ST3 and one electrode of the fourth transistor ST4 may be connected to an initialization voltage line VIL and another voltage line VAIL, respectively.

Alternatively, the driving transistor DT, the second transistor ST2, the fourth transistor ST4, the fifth transistor ST5, and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5, and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, because the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, because the second transistor ST2, the fourth transistor ST4, the fifth transistor ST5, and the sixth transistor ST6 are formed as p-type MOSFETs, they may be turned on in response to a scan signal of a gate-low voltage and an emission control signal of a gate-low voltage.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

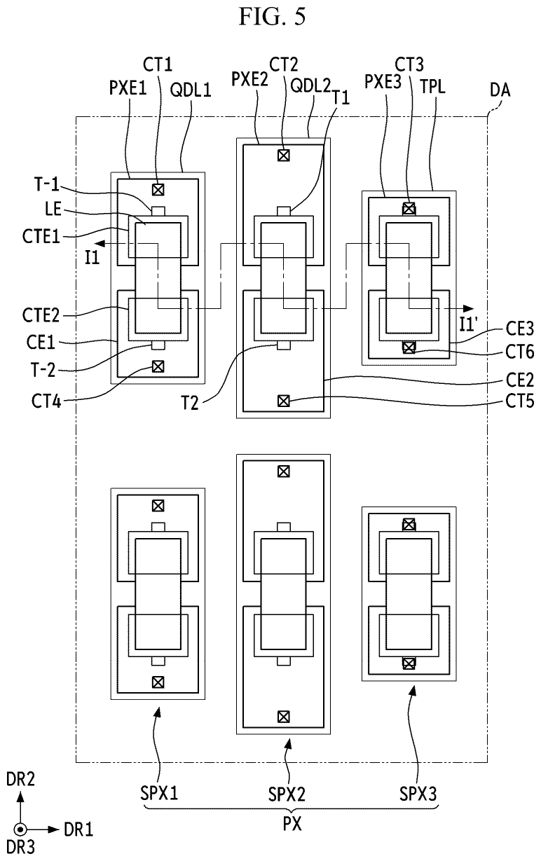

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the sub-pixels may include the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit a first light, the second sub-pixel SPX2 may emit a second light, and the third sub-pixel SPX3 may emit a third light. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit a first light, the second and fourth sub-pixels may emit a second light, and the third sub-pixel may emit a third light. Alternatively, the first sub-pixel may emit a first light, the second sub-pixel may emit a second light, the third sub-pixel may emit a third light, and the fourth sub-pixel may emit a fourth light. In this case, the fourth color light may be white light.

The first sub-pixel SPX1 includes a first pixel electrode PXE1, a first common electrode CE1, a plurality of light emitting elements LE, and a first light conversion layer QDL1. The second sub-pixel SPX2 includes a second pixel electrode PXE2, a second common electrode CE2, a plurality of light emitting elements LE, and a second light conversion layer QDL2. The third sub-pixel SPX3 includes a third pixel electrode PXE3, a third common electrode CE3, a plurality of light emitting elements LE, and a light transmission layer (or third light conversion layer) TPL.

Each of the first pixel electrode PXE1, the second pixel electrode PXE2, and the third pixel electrode PXE3 may have a rectangular planar shape with a short side in the first direction DR1 and a long side in the second direction DR2. Depending on the light conversion efficiency of the first light conversion layer QDL1 and the light conversion efficiency of the second light conversion layer QDL2, an area of the first sub-pixel SPX1, an area of the second sub-pixel SPX2, and an area of the third sub-pixel SPX3 may be set. For example, the lower the light conversion efficiency, the larger the area of the sub-pixel.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Also, the area of the first pixel electrode PXE1 may be larger than the area of the third pixel electrode PXE3 because the light transmission layer TPL transmits light from the light emitting element LE as it is, whereas the first light conversion layer QDL1 needs to convert light.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

Each of the pixel electrodes PXE1, PXE2, and PXE3 and the common electrodes CE1, CE2, and CE3 may have a rectangular planar shape. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

In the first sub-pixel SPX1, the first pixel electrode PXE1 and the first common electrode CE1 may be arranged to be spaced (e.g., spaced apart) in the second direction DR2. In the second sub-pixel SPX2, the second pixel electrode PXE2 and the second common electrode CE2 may be arranged to be spaced (e.g., spaced apart) in the second direction DR2. In the third sub-pixel SPX3, the third pixel electrode PXE3 and the third common electrode CE3 may be arranged to be spaced (e.g., spaced apart) in the second direction DR2.

The first common electrode CE1 may be connected to the second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3.

The plurality of light emitting elements LE may be disposed on each of the pixel electrodes PXE1, PXE2, and PXE3 and the common electrodes CE1, CE2, and CE3. At least a portion of the pixel electrodes PXE1, PXE2, and PXE3 and the common electrodes CE1, CE2, and CE3 may be exposed without the light emitting element LE disposed thereon. The same number of light emitting elements LE may be disposed on each of the pixel electrodes PXE1, PXE2, and PXE3 and the common electrodes CE1, CE2, and CE3. For example, two light emitting elements LE may be disposed on each of the pixel electrodes PXE1, PXE2, and PXE3. The plurality of light emitting elements LE may emit a third light, for example, light in a blue wavelength band, but the present disclosure is not limited thereto. When the light emitting element LE of the first sub-pixel SPX1 emits the first light, the light emitting element LE of the second sub-pixel SPX2 emits the second light, and the light emitting element LE of the third sub-pixel SPX3 emits the third light, the light conversion layers QDL1 and QDL2 and the light transmission layer TPL may be omitted.

The first light conversion layer QDL1 may completely overlap the first pixel electrode PXE1 and the plurality of light emitting elements LE of the first sub-pixel SPX1. The area of the first light conversion layer QDL1 may be larger than the sum of the areas of the first pixel electrode PXE1 and the first common electrode CE1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second pixel electrode PXE2 and the second sub-pixel SPX2. The area of the second light conversion layer QDL2 may be larger than the sum of the areas of the second pixel electrode PXE2 and the second common electrode CE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third pixel electrode PXE3 and the third sub-pixel SPX3. The area of the light transmission layer TPL may be larger than the sum of the areas of the third pixel electrode PXE3 and the third common electrode CE3. For example, the light transmission layer TPL may directly transmit the third light emitted from the plurality of light emitting elements LE of the third sub-pixel SPX3.

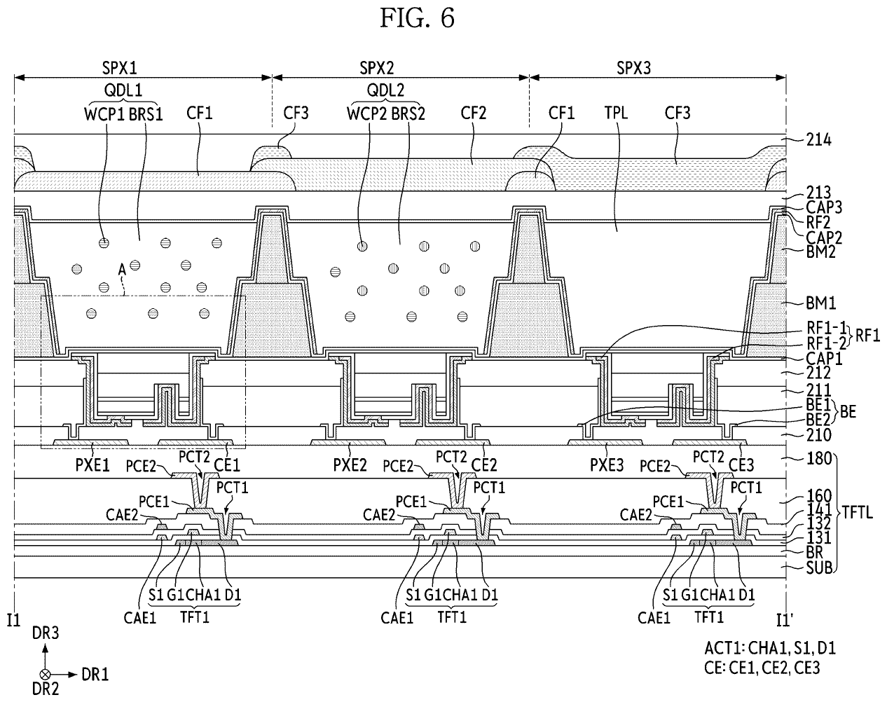

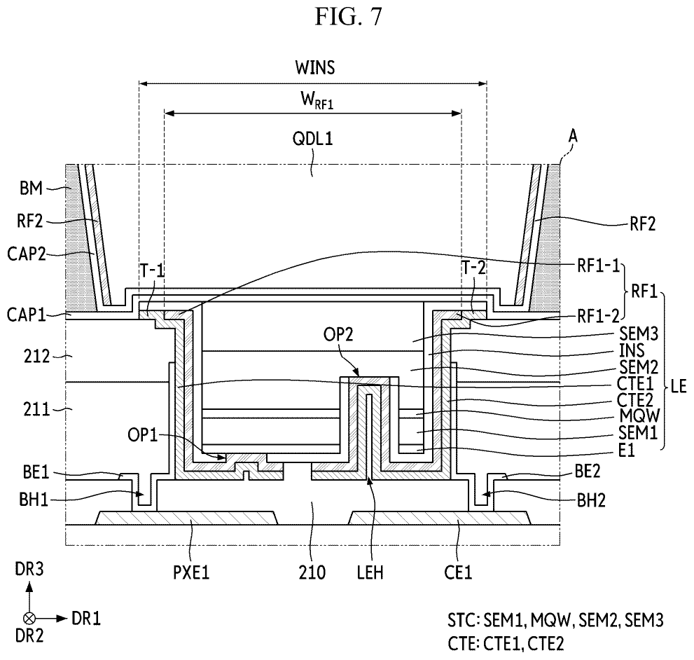

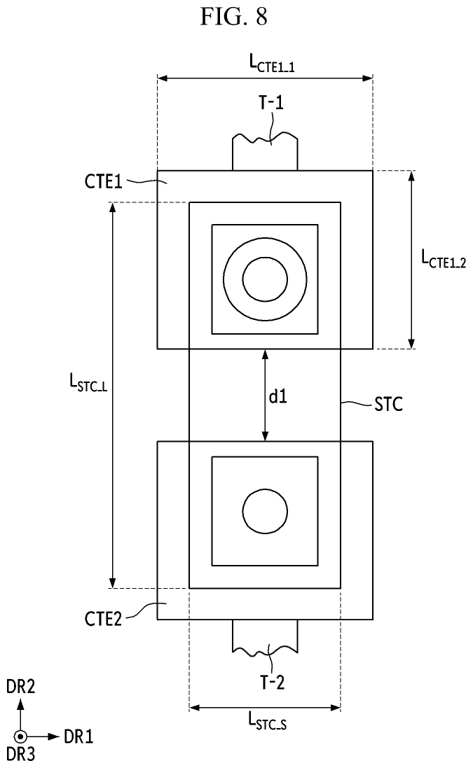

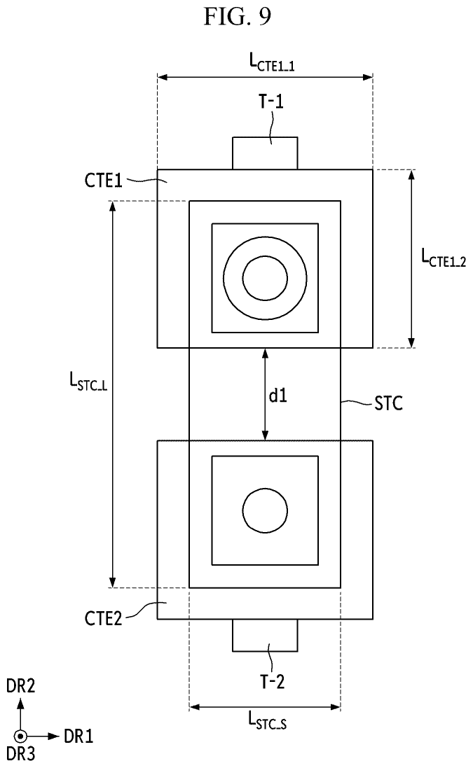

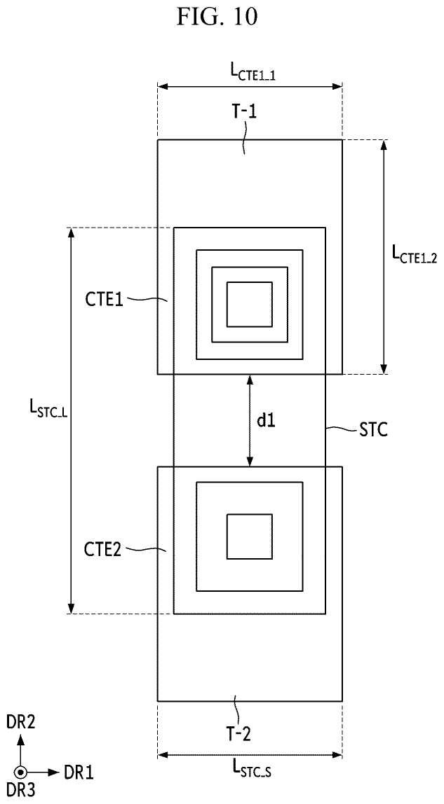

FIG. 6 is a cross-sectional view illustrating an example cross-section of one display panel corresponding to the lines I1-I1′ in FIG. 5. FIG. 7 is a cross-sectional view illustrating one example of an area A of FIG. 6 in detail. FIG. 8 is a plan view illustrating the light emitting element of FIG. 7 in detail. FIGS. 9 and 10 are plan views illustrating details of a light emitting element according to one or more other embodiments.

Referring to FIGS. 6 and 7, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a film to protect the transistors of the thin film transistor layer TFTL and the light emitting elements LE disposed on the thin film transistor layer TFTL from moisture penetrating through the substrate SUB, which is vulnerable to moisture penetration. The barrier film BR may be composed of a plurality of inorganic films stacked alternately.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1 and the barrier film BR.

A first gate metal layer may be disposed on the first gate insulating film 131. The first gate metal layer may include the first gate electrode G1 of the thin film transistor TFT1 and the first capacitor electrode CAE1. The first gate electrode G1 may overlap the first active layer ACT1 in the third direction DR3. In FIG. 6, the first gate electrode G1 and the first capacitor electrode CAE1 are shown as being spaced from each other, but the first gate electrode G1 and the first capacitor electrode CAE1 may be electrically or physically connected to each other when the thin film transistor TFT1 is the driving transistor DT of FIG. 4. Alternatively, in another embodiment, the first gate electrode G1 and the first capacitor electrode CAE1 may not be electrically or physically connected to each other. Alternatively, when the thin film transistor TFT1 is one of the first to sixth transistors ST1 to ST6 in FIG. 4, the first gate electrode G1 and the first capacitor electrode CAE1 may not be electrically or physically connected to each other.

A second gate insulating film 132 may be disposed on the first gate electrode G1 of the thin film transistor TFT1, the first capacitor electrode CAE1, and the first gate insulating film 131.

A second gate metal layer may be disposed on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2 and the second gate insulating film 132.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization film 160 may be disposed on the first source connection electrode PCE1 and the interlayer insulating film 141 to planarize a step caused by the thin film transistor TFT1.

A second data metal layer may be disposed on the first planarization film 160. The second data metal layer may include a second source connection electrode PCE2. The second source connection electrode PCE2 may be connected to the first source connection electrode PCE1 through a second source contact hole PCT2 penetrating the first planarization film 160.

A second planarization film 180 may be disposed on the second source connection electrode PCE2 and the first planarization film 160.

The barrier film BR, the first gate insulating film 131, the second gate insulating film 132, and the interlayer insulating film 141 may be formed from inorganic films, such as silicon nitride (SiNx), silicon nitride oxide (SiON), silicon oxide (SiOx), titanium oxide (TiOx), and/or aluminum oxide (AlOx).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization film 160 and the second planarization film 180 may be formed of an organic film such as an acrylic resin, an epoxy resin, a phenolic resin, a polyamide resin, a polyimide resin, and/or the like.

A light emitting element layer may be disposed on the second planarization film 180. The light emitting element layer may include pixel electrodes PXE1, PXE2, PXE3, light emitting elements LE, a common electrode CE (CE1, CE2, CE3), and organic films 210, 211, and 212.

A pixel electrode layer may be disposed on the second planarization film 180. The pixel electrode layer may include pixel electrodes PXE1, PXE2, and PXE3 and common electrodes CE1, CE2, and CE3. Each of the pixel electrodes PXE1, PXE2, and PXE3 may be connected to the second source connection electrode PCE2 through a pixel connection hole (CT1/CT2/CT3 in FIG. 5) penetrating the second planarization film 180. Each of the pixel electrodes PXE1, PXE2, and PXE3 may be connected to a first source area S1 or a first drain area D1 of the thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The pixel electrode layer may be formed as a single layer or multiple layers of molybdenum (Mo), aluminum (Al), chromium (Cr), gold (Au), titanium (Ti), nickel (Ni), neodymium (Nd), and/or copper (Cu), and/or alloys thereof. For example, the pixel electrode layer may be made of copper (Cu) with low sheet resistance to lower the resistance of each of the pixel electrodes PXE1, PXE2, and PXE3.

A first organic film 210 may be disposed on each of the pixel electrodes PXE1, PXE2, and PXE3 and the second planarization film 180. The first organic film 210 serves to temporarily fix or adhere the plurality of light emitting elements LE to prevent the plurality of light emitting elements LE from tipping over or falling down in the process of transferring the plurality of light emitting elements LE to the display panel 100. That is, the first organic film 210 may be a film for temporarily adhering the plurality of light emitting elements LE to each of the pixel electrodes PXE1, PXE2, and PXE3. To facilitate temporary adhesion, the thickness of the first organic film 210 may be greater than the thickness of each of the pixel electrodes PXE1, PXE2, and PXE3 and greater than the thickness of the contact electrode CTE (CTE1, CTE2).

The first organic film 210 may be a photosensitive organic layer such as photoresist. Alternatively, the first organic film 210 may be formed from an acrylic resin, an epoxy resin, a phenolic resin, a polyamide resin, a polyimide resin, and/or the like.

The plurality of light emitting elements LE may be disposed on the first organic film 210. FIG. 6 illustrates that each of the plurality of light emitting elements LE is a flip-type micro LED.

The flip-type micro LED refers to an LED in which contact electrodes CTE1 and CTE2 are formed on at least one side (e.g., the bottom side) of the light emitting element LE.

A semiconductor stack STC of the light emitting element LE may include a first semiconductor layer SEM1, an active layer MQW, a second semiconductor layer SEM2, and a third semiconductor layer SEM3.

Each of the plurality of light emitting elements LE may be formed of an inorganic material such as gallium nitride (GaN). Each of the plurality of light emitting elements LE may have a length in the first direction DR1, a length in the second direction DR2, and a length in the third direction DR3 of several to hundreds of um, respectively.

Each of the plurality of light emitting elements LE may be formed by growing on a semiconductor substrate such as a silicon substrate and/or sapphire substrate. The plurality of light emitting elements LE may be directly transferred from the semiconductor substrate on the pixel electrodes PXE1, PXE2, and PXE3 and the common electrodes CE1, CE2, and CE3 of the display panel 100. Alternatively, the plurality of light emitting elements LE may be transferred onto the pixel electrodes PXE1, PXE2, and PXE3 of the display panel 100 through an electrostatic method using an electrostatic head and/or a stamp method using an elastic polymeric material such as PDMS or silicone as a transfer substrate.

The light emitting element LE may include a conductive layer E1, a semiconductor stack STC, contact electrodes CTE1 and CTE2, a first reflective layer RF1, and a protective film INS.

The conductive layer E1 may be disposed on the lower surface of the first semiconductor layer SEM1. Although FIG. 7 illustrates that the conductive layer E1 covers the entire lower surface of the first semiconductor layer SEM1, the present disclosure is not limited thereto. In one example, the conductive layer E1 may be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The semiconductor stack STC may include a first semiconductor layer SEM1, an active layer MQW, a second semiconductor layer SEM2, and a third semiconductor layer SEM3 sequentially arranged along the third direction DR3.

The first semiconductor layer SEM1 may be disposed on the conductive layer E1. A length of the bottom surface of the first semiconductor layer SEM1 in the first direction DR1 and/or the length in the second direction DR2 may be smaller than a length in the first direction DR1 and/or a length in the second direction DR2 of the contact electrode CTE. The first semiconductor layer SEM1 may include a semiconductor material layer doped with a first conductive dopant, such as magnesium (Mg), zinc (Zn), calcium (Ca), strontium (Sr), barium (Ba), and/or the like, such as gallium nitride (GaN).

The active layer MQW may be disposed on the first semiconductor layer SEM1. The active layer MQW may include the same semiconductor material layer as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN and/or AlGaN but is not limited thereto. Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the active layer MQW. The second semiconductor layer SEM2 may be a semiconductor material layer doped with a second conductivity type dopant such as silicon (Si), germanium (Ge), tin (Sn), etc., for example, gallium nitride (GaN).

The third semiconductor layer SEM3 may be disposed on the second semiconductor layer SEM2.

The third semiconductor layer SEM3 may be a semiconductor material layer in which the n-type dopant is lower than a suitable threshold value (e.g., a predetermined threshold value) and may be referred to as an un-doped semiconductor layer. For example, the third semiconductor layer SEM3 may be indium aluminum gallium nitride (InAIGaN), gallium nitride (GaN), aluminum gallium nitride (AIGaN), indium gallium nitride (InGaN), aluminum nitride (AIN), and/or indium nitride (InN), where the n-type dopant is lower than a suitable threshold (e.g., a predetermined threshold).

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be AlGaN and/or p-AIGaN doped with p-type Mg. The electron blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

The protective film INS may be disposed on a side (e.g., an outer peripheral surface) of the conductive layer E1, a side (e.g., an outer peripheral surface) of the first semiconductor layer SEM1, a side (e.g., an outer peripheral surface) of the active layer MQW, a side (e.g., an outer peripheral surface) of the second semiconductor layer SEM2, and a side (e.g., an outer peripheral surface) of the third semiconductor layer SEM3. The protective film INS may be a film to protect the side surface of the light emitting element LE. The protective film INS may be formed of an inorganic film, such as silicon nitride (SiNx), silicon oxide (SiON), silicon oxide (SiOx), titanium oxide (TiOx), and/or aluminum oxide (AlOx).

In FIG. 7, the protective film INS is disposed on the side surfaces of the first semiconductor layer SEM1, the side surfaces of the active layer MQW, the side surfaces of the second semiconductor layer SEM2 and the side surfaces of the third semiconductor layer SEM3 of the semiconductor stack STC, the present disclosure is not limited thereto. In one example, the protective film INS is disposed on the side surfaces of the first semiconductor layer SEM1, the side surfaces of the active layer MQW, the side surfaces of the second semiconductor layer SEM2, and is not disposed at the sides of the third semiconductor layer SEM3 of the semiconductor stack STC.

A hole LEH exposing the second semiconductor layer SEM2 may be formed through the conductive layer E1, the first semiconductor layer SEM1, and the active layer MQW of the light emitting element LE. The hole LEH may have a circular planar shape, but the present disclosure is not limited thereto. For example, the hole LEH may have a polygonal plan shape such as an elliptical shape, or a rectangular shape.

In addition, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first reflective layer RF1 may be disposed on the protective layer INS and may be disposed on one side of the conductive layer E1, surrounding the side surfaces of the conductive layer E1 and the semiconductor stack STC.

The first reflective layer RF1 may extend from the side of the semiconductor stack STC on the protective layer INS and may protrude outward from the top surface of the semiconductor stack STC. The protrusion direction may be perpendicular to the direction of the extension surface. For example, the first reflective layer RF1 may protrude in an outward direction perpendicular to the side surface of the light emitting element LE.

The first reflective layer RF1 may be disposed lower than the height of the protective layer INS by the thickness of the protective layer INS. The first reflective layer RF1 may protrude less than the protective layer INS. One end of the first reflective layer RF1 may be disposed inside the protective layer INS. For example, the width W_{RF1} of the first reflective layer RF1 may be narrower than the width W_{INS} of the protective layer INS when viewed from the top of the light emitting element LE.

The first reflective layer RF1 may have an area spaced (e.g., spaced apart) from the first contact electrode CTE1 and the second contact electrode CTE2. For example, the first reflective layer RF1 may include a 1-1 reflective layer RF1-1 in contact with the first contact electrode CTE1 and a 1-2 reflective layer RF1-2 in contact with the second contact electrode CTE2. One end of the 1-1 reflective layer RF1-1 and one end of the 1-2 reflective layer RF1-2 are disposed on one surface of the light emitting element LE, and one end of the 1-1 reflective layer RF1-1 and one end of the 1-2 reflective layer RF1-2 are spaced (e.g., spaced apart) from each other. For example, the 1-1 reflective layer RF1-1 and the 1-2 reflective layer RF1-2 are not electrically connected. The other end of the 1-1 reflective layer RF1-1 and the other end of the 1-2 reflective layer RF1-2 protrude outward from the top surface of the light emitting element LE.

In one embodiment, the 1-1 reflective layer RF1-1 may be disposed on the conductive layer E1 exposed through the first opening OP1 of the protective layer INS. The 1-1 reflective layer RF1-1 is electrically connected to the conductive layer E1.

The 1-2 reflective layer RF1-2 may be disposed on the second semiconductor layer SEM2 exposed in the hole LEH and may extend to the side of the hole LEH. The 1-2 reflective layer RF1-2 is electrically connected to the second semiconductor layer SEM2 through the hole LEH.

In one or more embodiments, the first reflective layer RF1 may include a metal material that is conductive and has highly reflective of light (e.g., greater than 90% reflectivity). The first reflective layer RF1 may include, for example, aluminum (Al), chromium (Cr), and/or silver (Ag), and/or an alloy thereof, and may include a single layer or multiple layers thereof. The multilayer may be, for example, two layers of titanium/copper, two layers of titanium/aluminum, two layers of nickel/aluminum, two layers of a silver/aluminum-silicon alloy, etc. The first reflective layer RF1 allows light emitted from the light emitting element LE to be directed to the top.

The first contact electrode CTE1 may be disposed on the pixel electrode PXE of each sub-pixel SPX. For example, the first contact electrode CTE1 may be disposed between the pixel electrode PXE of each sub-pixel SPX and the light emitting element LE.

The first contact electrode CTE1 is disposed on the first reflective layer RF1 to follow the first reflective layer RF1, for example, the 1-1 reflective layer RF1-1. One end of the first contact electrode CTE1 is disposed on one surface of the semiconductor stack STC and is electrically connected to the conductive layer E1 through the 1-1 reflective layer RF1-1 on the first opening OP1. One end of the first contact electrode CTE1 extends along the side of the semiconductor stack STC, while the other end of the first contact electrode CTE1 protrudes outward from the top surface of the semiconductor stack STC. The protrusion direction may be perpendicular to the extension direction. For example, the first contact electrode CTE1 may protrude in an outward direction perpendicular to the side surface of the semiconductor stack STC. For convenience of explanation, a protruding portion of the first contact electrode CTE1 in an outward direction perpendicular to the side surface of the semiconductor stack STC may be referred to as a protrusion.

The other end of the first contact electrode CTE1 may be disposed lower than the height of the 1-1 reflective layer RF1-1 by the thickness of the 1-1 reflective layer RF1-1. The first contact electrode CTE1 may protrude further than the 1-1 reflective layer RF1-1. For example, the protrusion length of the first reflective layer RF1-1 may be from about 0.6 μm to 2.4 μm, and the protrusion length of the first contact electrode CTE1 may be from about 1.2 μm to 4.8 μm.

The other end of the first contact electrode CTE1 may protrude further outward than the other end of the 1-1 reflective layer RF1-1. For example, the other end of the first contact electrode CTE1 may be aligned with the other end of the protective layer INS. The other end of the first contact electrode CTE1 may be arranged to be around (e.g., to surround) the other end of the 1-1 reflective layer RF1-1. The other end of the 1-1 reflective layer RF1-1 may be completely surrounded by the first contact electrode CTE1 and the protective layer INS.

The first contact electrode CTE1 may electrically connect the conductive layer E1 and the first semiconductor layer SEM1 of the light emitting element LE to the pixel electrode PXE of each sub-pixel SPX through the first connection electrode BE1, which will be described later.

The first contact electrode CTE1 may include a first tip T-1. The first tip T-1 may be integrated with the first contact electrode CTE1. The first tip T-1 may extend in a protruding direction of the protrusion of the first contact electrode CTE1 and may be disposed on the first surface of the first contact electrode CTE1. The width of the first tip T-1 may be smaller than the width of the semiconductor stack STC.

The second contact electrode CTE2 may be disposed on the common electrode CE of each sub-pixel SPX. For example, the second contact electrode CTE2 may be disposed between the common electrode CE and the light emitting element LE of each sub-pixel SPX. The second contact electrode CTE2 is disposed on the first reflective layer RF1 to follow the first reflective layer RF1, for example, the 1-2 reflective layer RF1-2. One end of the second contact electrode CTE2 may be disposed on one side of the semiconductor stack STC and extend to the side of the hole LEH. The second contact electrode CTE2 is electrically connected to the second semiconductor layer SEM2 through the 1-2 reflective layer RF1-2 in the hole LEH. One end of the second contact electrode CTE2 extends along the side of the semiconductor stack STC, while the other end of the second contact electrode CTE2 protrudes outward from the top surface of the semiconductor stack STC. The protrusion direction may be perpendicular to the direction of the extension surface. For example, the second contact electrode CTE2 may protrude in an outward direction perpendicular to the side surface of the semiconductor stack STC. For convenience of explanation, a protruding portion of the first contact electrode CTE1 in an outward direction perpendicular to the side surface of the semiconductor stack STC may be referred to as a protrusion.

In addition, one end of the first contact electrode CTE1 and the second contact electrode CTE2 may be disposed to be spaced (e.g., spaced apart) from each other. The first contact electrode CTE1 and the second contact electrode CTE2 are not electrically connected.

The other end of the second contact electrode CTE2 may be disposed lower than the height of the 1-2 reflective layer RF1-2 by the thickness of the 1-2 reflective layer RF1-2. The second contact electrode CTE2 may protrude further than the 1-2 reflective layer RF1-2. The protrusion length of the 1-2 reflective layer RF1-2 may be from about 0.6 μm to 2.4 μm, and the protrusion length of the second contact electrode CTE2 may be from about 1.2 μm to 4.8 μm.

The other end of the second contact electrode CTE2 may protrude further outward than the other end of the 1-2 reflective layer RF1-2. For example, the other end of the second contact electrode CTE2 may be aligned with the other end of the protective layer INS. The other end of the second contact electrode CTE2 may be arranged to be around (e.g., to surround) the other end of the 1-2 reflective layer RF1-2. The other end of the 1-2 reflective layer RF1-2 may be completely surrounded by the second contact electrode CTE2 and the protective layer INS.

The second contact electrode CTE2 may electrically connect the second semiconductor layer SEM2 of the light emitting element LE to the common electrode CE of each sub-pixel SPX through the second connection electrode BE2.

The second contact electrode CTE2 may include a second tip T-2. The second tip T-2 may be integrated with the second contact electrode CTE2. The second tip T-2 may extend in a protruding direction of the protrusion of the second contact electrode CTE2 and may be disposed on the first surface of the second contact electrode CTE2.

Referring to FIG. 8, a length of the long side L_{STC_L} of the semiconductor stack STC is about 25 μm and a length of the short side L_{STC-S} of the semiconductor stack STC is about 10 μm, a length of the long side L_{CTE1_2} of the first contact electrode CTE1 may be about 13 μm to 17 μm, and a length of the short side L_{CTE1_1} of the first contact electrode CTE1 may be about 13 μm to 15 μm. A separation distance d1 between the first contact electrode CTE1 and the second contact electrode CTE2 may be about 6 μm.

Referring to FIGS. 8 and 9, the second tip T-2 and the first tip T-1 may be disposed in a straight line on a plane. The second tip T-2 and the first tip T-1 may be disposed on a straight line parallel to the long side of the light emitting element LE.

Referring to FIG. 8, the width of the first tip T-1 and the second tip T-2 may be smaller than the width of the semiconductor stack STC. Further, the first tip T-1 and the second tip T-2 may have an irregular one-sided surface. Also, referring to FIG. 9, the first tip T-1 and the second tip T-2 may have one end surface that is smooth compared to FIG. 8.

In addition, referring to FIG. 10, the width of the first tip T-1 and the second tip T-2 may be larger than the width of the semiconductor stack STC.

The first contact electrode CTE1 and the second contact electrode CTE2 may include a metal, metal oxide, and/or other conductive material having a higher conductivity than the first reflective layer RF1. For example, the first contact electrode CTE1 and the second contact electrode CTE2 may include gold (Au), copper (Cu), and/or chromium (Cr).

While FIGS. 6 and 7 illustrate that the first contact electrode CTE1 and the second contact electrode CTE2 of each of the light emitting elements LE are disposed on the first organic film 210, the present disclosure is not limited to this. For example, the first organic film 210 may be disposed on a portion of the bottom surface and side surface of the first contact electrode CTE1 and a portion of the bottom surface and side surface of the second contact electrode CTE2 of each of the light emitting elements LE. Alternatively, the first organic film 210 may be disposed on the side surfaces of the conductive layer E1 of each light emitting element LE. Alternatively, the first organic film 210 may be disposed on the side surfaces of the first semiconductor layer SEM1, the side surfaces of the active layer MQW, and the side surfaces of the second semiconductor layer SEM2 of each of the light emitting elements LE. In this case, the first organic film 210 may be disposed on a portion of each side of the second semiconductor layer SEM2.

Each of the first and second contact electrodes CTE1 and CTE2 may be disposed on three sides of the semiconductor stack STC. For example, when the semiconductor stack STC includes first to fourth sides, the first contact electrode CTE1 may be disposed on the first side, the second side, and the third side, and the second contact electrode CTE2 may be disposed on the second side, third side, and fourth side. However, in one or more embodiments, each of the first and second contact electrodes CTE1 and CTE2 may be disposed on two sides of the semiconductor stack STC (e.g., FIG. 7).

The contact electrode CTE may include molybdenum (Mo), aluminum (Al), chromium (Cr), gold (Au), titanium (Ti), nickel (Ni), neodymium (Nd), and/or copper (Cu).

The first connection electrode BE1 connects the first contact electrode CTE1 of the light emitting element LE and the pixel electrodes PXE1, PXE2, and PXE3. The first connection electrode BE1 may be connected to the exposed pixel electrodes PXE1, PXE2, and PXE3 through a first connection hole BH1 penetrating the first organic film 210. Further, the first connection electrode BE1 may be disposed on the top surface of the first organic film 210 and the first contact electrode CTE1.

The second connection electrode BE2 connects the second contact electrode CTE2 of the light emitting element LE and the common electrodes CE1, CE2, and CE3. The second connection electrode BE2 may be connected to the exposed common electrodes CE1, CE2, and CE3 through a second connection hole BH2 penetrating the first organic film 210. Further, the second connection electrode BE2 may be disposed on the top surface of the first organic film 210 and the second contact electrode CTE2.

The first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu). Alternatively, each of the first connection electrode BE1 and the second connection electrode BE2 may be made of a transparent conductive material (TCO) such as indium tin oxide (ITO) and/or indium zinc oxide (IZO).

As shown in FIGS. 6 and 7, the conductive layer E1 of the light emitting element LE may be connected to the pixel electrodes PXE1, PXE2, and PXE3 through the first reflective layer RF1, the first contact electrode CTE1 and the first connection electrode BE1. Further, the second semiconductor layer SEM2 of the light emitting element LE may be connected to the common electrodes CE1, CE2, and CE3 through the first reflective layer RF1, the second contact electrode CTE2 formed in the hole LEH and the second connection electrode BE2.

Referring back to FIGS. 6 and 7, a third organic layer 211 may partially cover the side surfaces of the light emitting elements LE. In addition, the third organic layer 211 may cover the connection electrodes BE (BE1, BE2), but at least a portion of each of the connection electrodes BE (BE1, BE2) may be exposed without being covered by the third organic layer 211.

A fourth organic layer 212 may be disposed on the third organic layer 211. The fourth organic layer 212 may partially cover the side surfaces of each of the light emitting elements LE. The fourth organic layer 212 may be disposed on at least a portion of each of the connection electrodes BE (BE1, BE2) exposed without being covered by the third organic layer 211. An upper surface of each of the light emitting elements LE may be exposed without being covered by the fourth organic layer 212.

The third organic layer 211 and the fourth organic layer 212 may be made of an organic layer such as acryl resin, epoxy resin, phenolic resin, polyamide resin, and/or polyimide resin.

The third organic layer 211 and the fourth organic layer 212 are layers for flattening steps caused by the light emitting elements LE. If the third organic layer 211 is high enough to cover most of the side surfaces of each of the light emitting elements LE, the fourth organic layer 212 may be omitted.

A first capping layer CAP1 may be disposed on the upper surface of each of the light emitting elements LE and an upper surface of the fourth organic layer 212. The first capping layer CAP1 may be a common layer commonly formed in a first subpixel SPX1, a second subpixel SPX2, and a third subpixel SPX3.

A light blocking layer BM (BM1, BM2), a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be separated and/or partitioned by the light blocking layer BM. Therefore, the first light conversion layer QDL1 may be disposed on the first capping layer CAP1 in the first subpixel SPX1, the second light conversion layer QDL2 may be disposed on the first capping layer CAP1 in the second subpixel SPX2, and the light transmission layer TPL may be disposed on the first capping layer CAP1 in the third subpixel SPX3. The light blocking layer BM may overlap the third organic layer 211 and the fourth organic layer 212 in the third direction DR3 and may not overlap the light emitting elements LE.

The first light conversion layer QDL1 may convert a portion of light of the third color (e.g., light in the blue wavelength band) incident from a light emitting element LE into light of the first color (e.g., light in the red wavelength band). The first light conversion layer QDL1 may include a first base resin BRS1 and first wavelength conversion particles WCP1. The first base resin BRS1 may include a light-transmitting organic material. The first wavelength conversion particles WCP1 may convert a portion of the light of the third color (e.g., light in the blue wavelength band) incident from the light emitting element LE into the light of the first color (e.g., light in the red wavelength band).

The second light conversion layer QDL2 may convert a portion of light of the third color (e.g., light in the blue wavelength band) incident from a light emitting element LE into light of the second color (e.g., light in the green wavelength band). The second light conversion layer QDL2 may include a second base resin BRS2 and second wavelength conversion particles WCP2. The second base resin BRS2 may include a light-transmitting organic material. The second wavelength conversion particles WCP2 may convert a portion of the light of the third color (e.g., light in the blue wavelength band) incident from the light emitting element LE into the light of the second color (e.g., light in the green wavelength band).

The light transmission layer TPL may include a light-transmitting organic material.

For example, the first base resin BRS1, the second base resin BRS2, and the light transmission layer TPL may include epoxy resin, acrylic resin, cardo resin, and/or imide resin. The first and second wavelength conversion particles WCP1 and WCP2 may be quantum dots, quantum rods, fluorescent materials, and/or phosphorescent materials.

The light blocking layer BM may include a first light blocking layer BM1 and a second light blocking layer BM2 stacked sequentially. A length of the first light blocking layer BM1 in the first direction DR1 and/or a length of the first light blocking layer BM1 in the second direction DR2 may be greater than a length of the second light blocking layer BM2 in the first direction DR1 and/or a length of the second light blocking layer BM2 in the second direction DR2. The first light blocking layer BM1 and the second light blocking layer BM2 may be made of an organic layer such as acryl resin, epoxy resin, phenolic resin, polyamide resin, and/or polyimide resin. The first light blocking layer BM1 and the second light blocking layer BM2 may include a light blocking material to prevent light of a light emitting element LE of any one subpixel from travelling to a neighboring subpixel. For example, the first light blocking layer BM1 and the second light blocking layer BM2 may include an inorganic black pigment such as carbon black and/or an organic black pigment.

A second capping layer CAP2 may be disposed on the first capping layer CAP1 and the light blocking layer BM. The second capping layer CAP2 may be disposed on side and upper surfaces of the light blocking layer BM. For example, the second capping layer CAP2 may be disposed on side surfaces of the first light blocking layer BM1 and side and upper surfaces of the second light blocking layer BM2 and on the first capping layer CAP1.

A second reflective layer RF2 may be disposed between the light blocking layer BM and the first light conversion layer QDL1, between the light blocking layer BM and the second light conversion layer QDL2, and between the light blocking layer BM and the light transmission layer TPL. The second reflective layer RF2 may be disposed on the second capping layer CAP2 disposed on the side surfaces of the first light blocking layer BM1 and the side surfaces of the second light blocking layer BM2. The second reflective layer RF2 may reflect light travelling in the lateral direction from the first light conversion layer QDL1, the second light conversion layer QDL2, and the light transmission layer TPL.

The second reflective layer RF2 may include a metal material with high reflectivity, such as aluminum (Al). A thickness of the second reflective layer RF2 may be about 0.1 μm.

Alternatively, to serve as distributed Bragg reflectors, the second reflective layer RF2 may include M (M is an integer of 2 or more) pairs of first and second layers having different refractive indices. In this case, M first layers and M second layers may be arranged alternately. The first and second layers may be made of an inorganic layer, for example, a silicon nitride layer, a silicon oxynitride layer, a silicon oxide layer, a titanium oxide layer, and/or an aluminum oxide layer.

A third capping layer CAP3 may be disposed on the second reflective layer RF2, the second capping layer CAP2, the first light conversion layer QDL1, the second light conversion layer QDL2, and the light transmission layer TPL.

The first capping layer CAP1, the second capping layer CAP2, and the third capping layer CAP3 may be made of an inorganic layer, for example, a silicon nitride layer, a silicon oxynitride layer, a silicon oxide layer, a titanium oxide layer, and/or an aluminum oxide layer. The first light conversion layer QDL1, the second light conversion layer QDL2, and the light transmission layer TPL may be encapsulated by the first capping layer CAP1, the second capping layer CAP2, and the third capping layer CAP3.

A fifth organic layer 213 may be disposed on the third capping layer CAP3. A plurality of color filters CF1 through CF3 may be disposed on the fifth organic layer 213. The color filters CF1 through CF3 may include first color filters CF1, second color filters CF2, and third color filters CF3.

A first color filter CF1 disposed in the first subpixel SPX1 may transmit light of the first color (e.g., light in the red wavelength band) and absorb and/or block light of the third color (e.g., light in the blue wavelength band). Therefore, the first color filter CF1 may transmit the light of the first color (e.g., light in the red wavelength band) into which a portion of the light of the third color (e.g., light in the blue wavelength band) emitted from a light emitting element LE has been converted by the first light conversion layer QDL1 and may absorb and/or block the light of the third color (e.g., light in the blue wavelength band) which has not been converted by the first light conversion layer QDL1. Accordingly, the first subpixel SPX1 may output the light of the first color (e.g., light in the red wavelength band).

A second color filter CF2 disposed in the second subpixel SPX2 may transmit light of the second color (e.g., light in the green wavelength band) and absorb and/or block light of the third color (e.g., light in the blue wavelength band). Therefore, the second color filter CF2 may transmit the light of the second color (e.g., light in the green wavelength band) into which a portion of the light of the third color (e.g., light in the blue wavelength band) emitted from a light emitting element LE has been converted by the second light conversion layer QDL2 and may absorb or block the light of the third color (e.g., light in the blue wavelength band) which has not been converted by the second light conversion layer QDL2. Accordingly, the second subpixel SPX2 may output the light of the second color (e.g., light in the green wavelength band).

A third color filter CF3 disposed in the third subpixel SPX3 may transmit light of the third color (e.g., light in the blue wavelength band). Therefore, the third color filter CF3 may transmit the light of the third color (e.g., light in the blue wavelength band) that passes through the light transmission layer TPL after being emitted from a light emitting element LE. Accordingly, the third subpixel SPX3 may emit the light of the third color (e.g., light in the blue wavelength band).

The first color filter CF1, the second color filter CF2, and the third color filter CF3 overlapping each other in the third direction DR3 may overlap the light blocking layer BM in the third direction DR3.

A sixth organic layer 214 for planarization may be disposed on the color filters CF1 through CF3.

The fifth organic layer 213 and the sixth organic layer 214 may be made of acryl resin, epoxy resin, phenolic resin, polyamide resin, and/or polyimide resin.

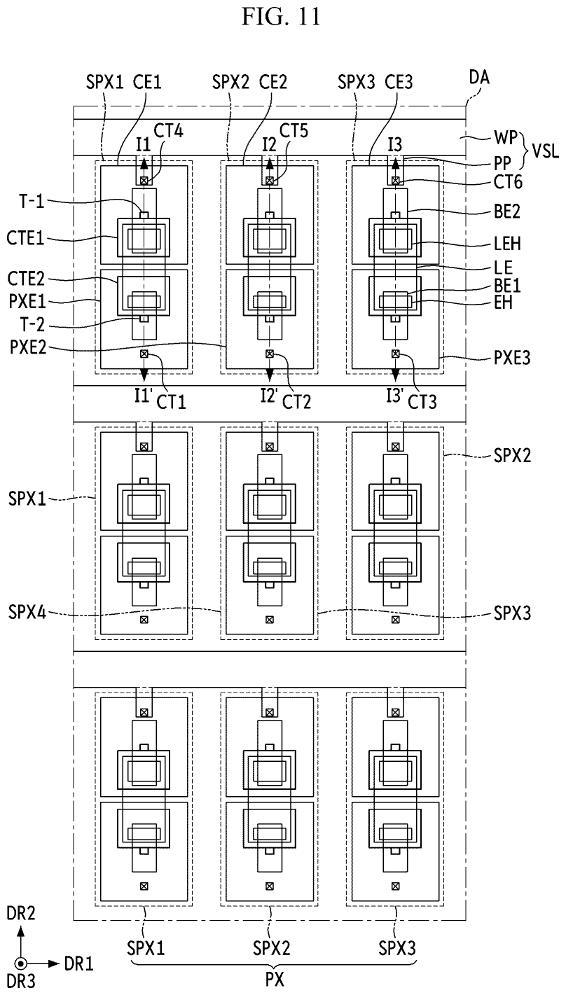

FIG. 11 is a layout diagram illustrating pixels of a display area according to one or more embodiments.

The embodiment of FIG. 11 differs from the embodiment of FIG. 5 in that the light emitting element LE in each of the first sub-pixel SPX1, the second sub-pixel SPX2, and the third sub-pixel SPX3 is disposed on a common electrode CE1, CE2, and CE3 with the pixel electrodes PXE1, PXE2, and PXE3 and may be substantially the same size. In the embodiment of FIG. 11, descriptions overlapping with the embodiment of FIG. 5 will be omitted.

Referring to FIG. 11, pixel electrodes PXE1, PXE2, and PXE3 and common electrodes CE1, CE2, and CE3 in each of the first sub-pixel SPX1, the second sub-pixel SPX2, and the third sub-pixel SPX3 may be arranged along the second direction DR2. The first pixel electrode PXE1 and the first common electrode CE1 may be arranged to be spaced (e.g., spaced apart) from each other. The second pixel electrode PXE2 and the second common electrode CE2 may be arranged to be spaced (e.g., spaced apart) from each other. The third pixel electrode PXE3 and the third common electrode CE3 may be arranged to be spaced (e.g., spaced apart) from each other.

The first sub-pixel SPX1, the second sub-pixel SPX2, the third sub-pixel SPX3, the first common electrode CE1, the second common electrode CE2, and the third common electrode CE3, respectively may have a rectangular planar shape, but the present disclosure is not limited thereto. Further, the area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

The first common electrode CE1 may be connected to the second power supply line VSL to which the second driving voltage VSS is applied through the first common connection hole CT4. The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The first connection electrode BE1 is connected to the conductive layer E1 of the light emitting element LE and the pixel electrodes PXE1, PXE2, and PXE3. The first connection electrode BE1 may overlap the hole EH exposing the conductive layer E1. The first connection electrode BE1 may overlap at least a portion of the pixel electrodes PXE1, PXE2, and PXE3.

The second connection electrode BE2 may be connected to the second semiconductor layer SEM2 of the light emitting element LE and the common electrodes CE1, CE2, and CE3. The second connection electrode BE2 may overlap the hole LEH exposing the second semiconductor layer SEM2. The second connection electrode BE2 may overlap at least a portion of the common electrodes CE1, CE2, and CE3.

Each of the second power supply lines VSL may include a line portion WP extending in the first direction DR1 and a protrusion PP projecting from the line portion WP in the second direction DR2 that overlaps the second pixel connection hole CT4, CT5, CT6.

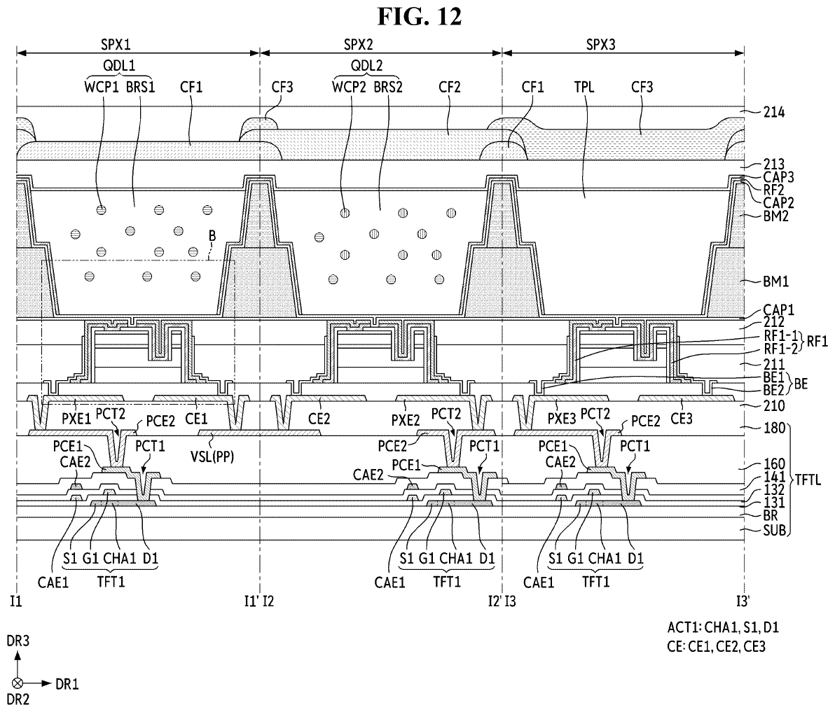

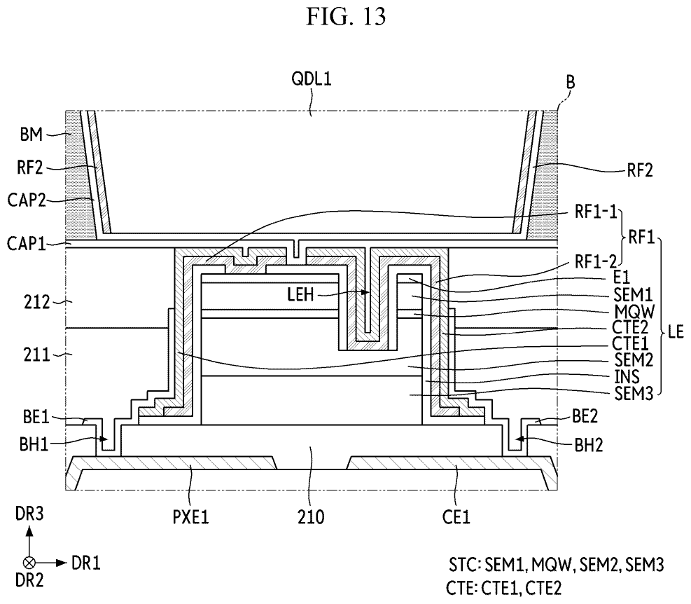

FIG. 12 is a cross-sectional view illustrating an example of a cross-section of a display panel corresponding to the lines I1-I1′, I2-I2′, and I3-I3′ in FIG. 11. FIG. 13 is a cross-sectional view illustrating one example of an area B in FIG. 12 in detail.

The embodiments of FIGS. 12 and 13 differ from the embodiments of FIGS. 6 and 7 in that the light emitting element LE is a lateral type micro LED. In the embodiments of FIGS. 12 and 13, descriptions overlapping with those of the embodiments of FIGS. 6 and 7 will be omitted.

Referring to FIGS. 12 and 13, the light emitting element LE may be disposed on the first organic film 210 in each of the sub-pixels SPX1, SPX2, and SPX3. The light emitting element LE is illustrated as a lateral type micro LED with current flowing in the lateral direction.

The light emitting element LE may include a conductive layer E1, a semiconductor stack STC, contact electrodes CTE1 and CTE2, a first reflective layer RF1, and a protective film INS.

While FIG. 13 illustrates the protective film INS disposed on the sides of the conductive layer E1, the sides of the first semiconductor layer SEM1, the sides of the active layer MQW, the sides of the second semiconductor layer SEM2, and the sides of the third semiconductor layer SEM3 of the semiconductor stack STC, the present disclosure is not limited thereto. In one example, the protective film may be disposed on the side surfaces of the conductive layer E1, the side surfaces of the first semiconductor layer SEM1, the side surfaces of the active layer MQW, the side surfaces of the second semiconductor layer SEM2, and not on the sides of the third semiconductor layer SEM3 of the semiconductor stack STC.

A hole LEH may be formed through the conductive layer E1, the first semiconductor layer SEM1, and the active layer MQW of the light emitting element LE to expose the second semiconductor layer SEM2. The hole LEH may have a circular planar shape, but the present disclosure is not limited thereto. For example, the hole LEH may have a polygonal plan shape such as an elliptical shape, or a rectangular shape.

In addition, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first reflective layer RF1 may be disposed on the protective layer INS and may be disposed on one side of the conductive layer E1, around (e.g., surrounding) the conductive layer E1 and the sides of the semiconductor stack STC.

The first reflective layer RF1 may extend from the side of the semiconductor stack STC on the protective layer INS and may protrude outward from one side of the semiconductor stack STC. The protrusion direction may be perpendicular to the direction of the extension surface. For example, the first reflective layer RF1 may protrude in an outward direction perpendicular to the side surface of the light emitting element LE.

The first reflective layer RF1 may protrude less than the protective layer INS. One end of the first reflective layer RF1 may be disposed inwardly of the protective layer INS. For example, the width W_{RF1} (e.g., see FIG. 7) of the first reflective layer RF1 may be narrower than the width W_{INS} (e.g., see FIG. 7) of the protective layer INS when viewed from the top of the light emitting element LE.

The first reflective layer RF1 may have an area spaced (e.g., spaced apart) from the first contact electrode CTE1 and the second contact electrode CTE2. For example, the first reflective layer RF1 may include a 1-1 reflective layer RF1-1 in contact with the first contact electrode CTE1 and a 1-2 reflective layer RF1-2 in contact with the second contact electrode CTE2. One end of the 1-1 reflective layer RF1-1 and one end of the 1-2 reflective layer RF1-2 are disposed on the first side of the light emitting element LE, and one end of the 1-1 reflective layer RF1-1 and one end of the 1-2 reflective layer RF1-2 are spaced (e.g., spaced apart) from each other. For example, the 1-1 reflective layer RF1-1 and the 1-2 reflective layer RF1-2 are not electrically connected. The other end of the 1-1 reflective layer RF1-1 and the other end of the 1-2 reflective layer RF1-2 protrude outwardly from the surfaces of the light emitting element LE.

In one or more embodiments, the 1-1 reflective layer RF1-1 may be disposed on the conductive layer E1 exposed through the first opening OP1 (e.g., FIG. 7) of the protective layer INS. The 1-1 reflective layer RF1-1 is electrically connected to the conductive layer E1.

The 1-2 reflective layer RF1-2 may be disposed on the second semiconductor layer SEM2 exposed in the hole LEH and may extend to the side of the hole LEH. The 1-2 reflective layer RF1-2 is electrically connected to the second semiconductor layer SEM2 through the hole LEH.

In one or more embodiments, the first reflective layer RF1 may include a metallic material that is conductive and highly reflective of light (e.g., greater than 90% reflectivity). The first reflective layer RF1 may include, for example, aluminum (Al), chromium (Cr), and/or silver (Ag), and/or an alloy thereof, and may comprise a single layer or multiple layers thereof. The multiple layers may be, for example, two layers of titanium/copper, two layers of titanium/aluminum, two layers of nickel/aluminum, two layers of a silver/aluminum-silicon alloy, etc. The first reflective layer RF1 allows light emitted from the light emitting element LE to be directed to the top.

The first contact electrode CTE1 may be disposed on at least one side of the semiconductor stack STC and on at least one side and bottom of the conductive layer E1. The first contact electrode CTE1 may be disposed on the exposed bottom surface of the conductive layer E1 that is not covered by the protective film INS. Therefore, the first contact electrode CTE1 may be electrically connected to the conductive layer E1 through the 1-1 reflective layer RF1-1.

The second contact electrode CTE2 may be disposed on at least one side of the semiconductor stack STC and on at least one side and bottom of the conductive layer E1. In this case, the first contact electrode CTE1 may be disposed on a first side of the semiconductor stack STC and a first side of the conductive layer E1, while the second contact electrode CTE2 may be disposed on a second side of the semiconductor stack STC and a second side of the conductive layer E1.

The second contact electrode CTE2 may be disposed on the protective film INS disposed in the hole LEH and on the second semiconductor layer SEM2 exposed in the hole LEH without being covered by the protective film INS. Therefore, the second contact electrode CTE2 may be electrically connected to the second semiconductor layer SEM2 through the 1-2 reflective layer RF1-2 in the hole LEH.

In FIGS. 12 and 13, a third semiconductor layer SEM3 of each of the light emitting elements LE is disposed on the first organic film 210, but the present disclosure is not limited thereto. For example, the first organic film 210 may be disposed on the side surfaces of the third semiconductor layer SEM3 of each light emitting element LE. Alternatively, the first organic film 210 may be disposed on a portion of each side of the second semiconductor layer SEM2 of each of the light emitting elements LE.

Each of the first contact electrode CTE1 and the second contact electrode CTE2 may be disposed on three sides of the semiconductor stack STC. For example, when the semiconductor stack STC includes first to fourth sides, the first contact electrode CTE1 may be disposed on the first side, the second side, and the third side, and the second contact electrode CTE2 may be disposed on the second side, third side, and fourth side. However, in one or more embodiments, each of the first contact electrode CTE1 and the second contact electrode CTE2 may be disposed on two sides of the semiconductor stack STC.

The first contact electrode CTE1 may include a first tip T-1 (e.g., see FIG. 7). The first tip T-1 (e.g., see FIG. 7) may be integrated with the first contact electrode CTE1. The first tip T-1 may extend in a protruding direction of the protrusion of the first contact electrode CTE1 and may be disposed on the first surface of the first contact electrode CTE1. The width of the first tip T-1 may be smaller than the width of the semiconductor stack STC.

The second contact electrode CTE2 may include a second tip T-2. The second tip T-2 may be integrated with the second contact electrode CTE2. The second tip T-2 may extend in a protruding direction of the protrusion of the second contact electrode CTE2 and may be disposed on the first surface of the second contact electrode CTE2.

The first connection electrode BE1 connects the first contact electrode CTE1 of the light emitting element LE and the pixel electrodes PXE1, PXE2, and PXE3. The first connection electrode BE1 may be connected to the exposed pixel electrodes PXE1, PXE2, and PXE3 through the first connection hole BH1 penetrating the first organic film 210. Further, the first connection electrode BE1 may be disposed on the top surface of the first organic film 210, the protective film INS disposed on the side of the second semiconductor layer SEM2, the side of the third semiconductor layer SEM3, the side of the active layer MQW, and the first contact electrode CTE1.

The second connection electrode BE2 connects the second contact electrode CTE2 of the light emitting element LE with the common electrodes CE1, CE2, and CE3. The second connection electrode BE2 may be connected to the exposed common electrodes CE1, CE2, and CE3 through the second connection hole BH2 penetrating the first organic film 210. Further, the second connection electrode BE2 may be disposed on the top surface of the first organic film 210, the protective film INS disposed on the side of the second semiconductor layer SEM2, the side of the third semiconductor layer SEM3, the side of the active layer MQW, and the second contact electrode CTE2.

Each of the first connection electrode BE1 and the second connection electrode BE2 may comprise molybdenum (Mo), aluminum (Al), chromium (Cr), gold (Au), titanium (Ti), nickel (Ni), neodymium (Nd), and/or copper (Cu). Alternatively, each of the first connection electrode BE1 and the second connection electrode BE2 may be made of a transparent conductive material (TCO), such as indium tin oxide (ITO) and/or indium zinc oxide (IZO).

As shown in FIGS. 12 and 13, the conductive layer E1 of the light emitting element LE may be connected to the pixel electrodes PXE1, PXE2, and PXE3 through the first reflective layer RF1, the first contact electrode CTE1, and the first connection electrode BE1. Further, the second semiconductor layer SEM2 of the light emitting element LE may be connected to the common electrodes CE1, CE2, and CE3 through the first reflective layer RF1, the second contact electrode CTE2, and the second connection electrode BE2 formed in the hole LEH.

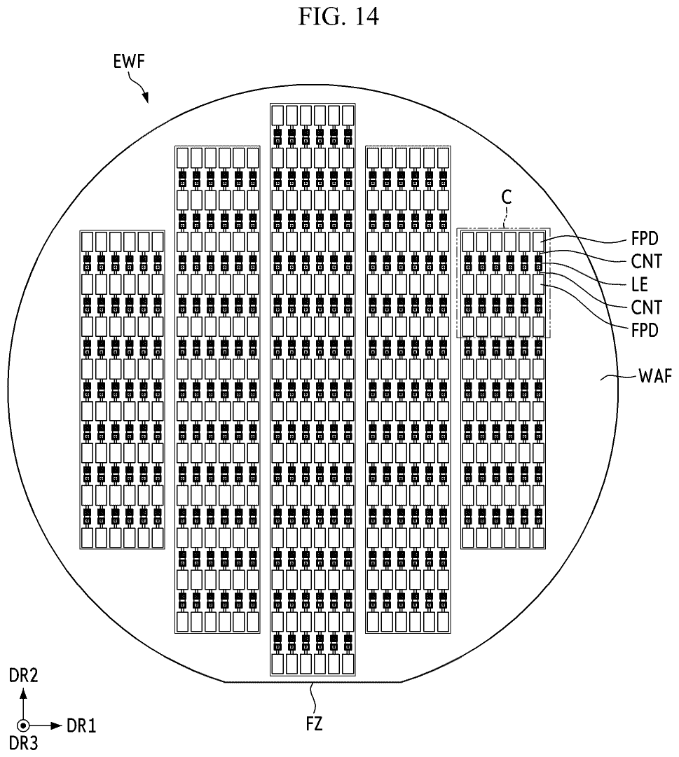

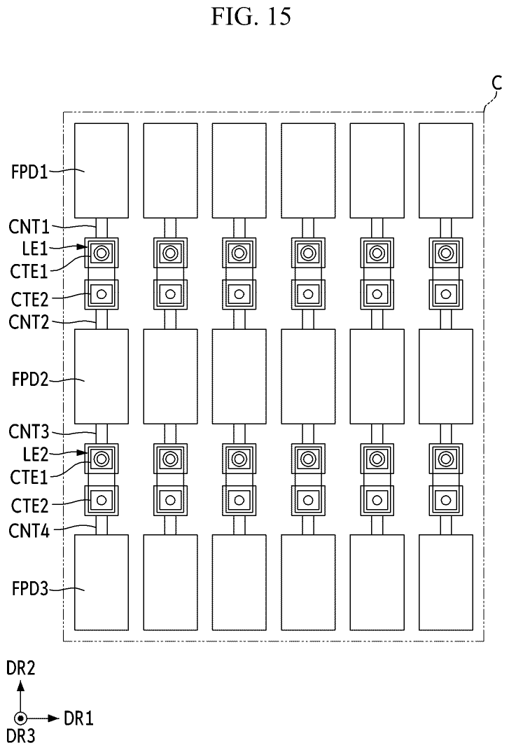

FIG. 14 is a layout diagram illustrating light emitting elements and pin pads on a wafer according to one or more embodiments. FIG. 15 is a layout view illustrating one example of an area C in FIG. 14 in detail.

Referring to FIGS. 14 and 15, the wafer EWF may include a wafer substrate WAF, a plurality of light emitting elements LE disposed on the WAF, a plurality of pin pads FPD, and a plurality of connectors CNT.

The wafer substrate WAF may be a semiconductor substrate suitable for epitaxial growth of a semiconductor. For example, the wafer substrate WAF may be a substrate containing a material such as silicon (Si), sapphire, SiC, GaN, GaAs, and/or ZnO. The type, material, and shape of the wafer substrate WAF are not particularly limited, as long as it may facilitate epitaxial growth to manufacture the light emitting element LE.

The wafer substrate WAF may include at least one of a flat zone FZ and/or a notch indicating the crystal orientation of the wafer.

The flat zone FZ is an area where the crystal surface of the wafer is flat. The notch is a triangular groove that indicates the crystal orientation of the wafer. In another variation, an alignment marker may be used instead of a flat zone FZ or notch.

In one or more embodiments, the wafer substrate WAF may be approximately 8 inches, 10 inches, or 12 inches in diameter. The wafer substrate WAF may be from a few to several hundred micrometers (μm) thick. Each length in the third direction DR3 may be approximately 100 μm or less.

The light emitting elements LE may be disposed on the wafer substrate WAF.

The plurality of light emitting elements LE may be arranged in a rectangular plane having a short side in the first direction DR1 and a long side in the second direction DR2 that intersects the first direction DR1.

The light emitting elements LE may be arranged adjacent to each other along the first direction DR1.

Because the light emitting elements LE may correspond to the light emitting elements LE described with reference to FIG. 7, redundant description will be omitted.

The pin pads FPD may be arranged in a rectangular plane having a short side in the first direction DR1 and a long side in the second direction DR2 that intersects the first direction DR1. The pin pads FPD have the smallest size for electrical measurement. For example, the area of each of the pin pads FPD may be larger than the area of the light emitting element LE.

The pin pads FPD may be arranged adjacent to each other along the first direction DR1.

The pin pad FPD and the light emitting elements LE may be alternately arranged along the second direction DR2 crossing the first direction DR1. For example, the light emitting element LE may be disposed adjacent to the pin pad FPD in the second direction DR2.

Each light emitting element LE is connected in series with the pin pad FPD through a connector CNT. The light emitting element LE may be electrically connected to pin pads FPD adjacent to each other in the second direction DR2. Further, the light emitting elements LE disposed in the second direction DR2 may share neighboring pin pads FPD. For example, in order in the second direction DR2, a first pin pad FPD1, a first light emitting element LE1, a second pin pad FPD2, a second light emitting element LE2, and a third pin pad FPD3 may be arranged.

The first light emitting element LE1 may be connected to the first pin pad FPD1 through a first connector CNT1 and may be connected to the second pin pad FPD2 by a second connector CNT2. The second light emitting element LE2 may be connected to the second pin pad FPD2 through a third connector CNT3 and may be connected to the third pin pad FPD3 through a fourth connector CNT4.

The first contact electrode CTE1 of the first light emitting element LE1 may be connected by the first pin pad FPD1 and the first connector CNT1, and the second contact electrode CTE2 of the first light emitting element LE1 may be connected by the second pin pad FPD2 and the second connector CNT2. The first contact electrode CTE1 of the second light emitting element LE2 may be connected by the second pin pad FPD2 and the third connector CNT3, and the second contact electrode CTE2 of the second light emitting element LE2 may be connected by the third pin pad FPD3 and the fourth contactor CNT4. In this way, the second pin pad FPD2 may be connected with the neighboring the first light emitting element LE1 and the second light emitting element LE2.

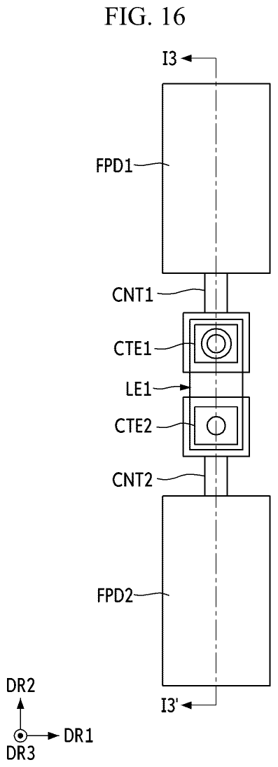

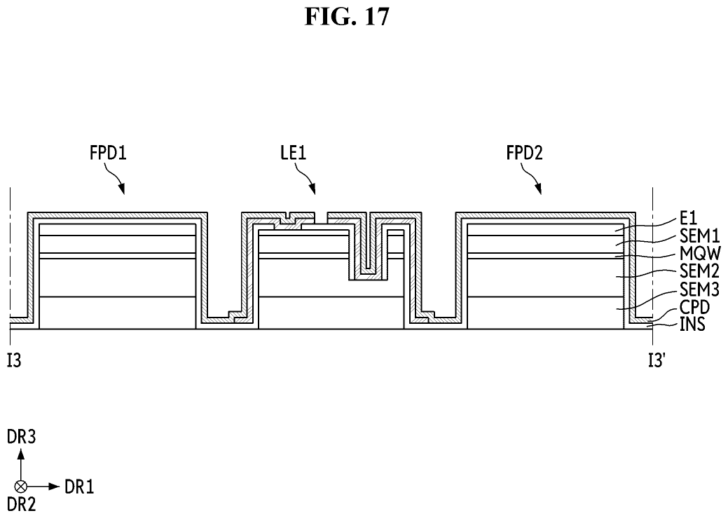

FIG. 16 is a plan view illustrating one test block of FIG. 14 in detail. FIG. 17 is a cross-sectional view illustrating the test block of FIG. 16 in detail.

Referring to FIGS. 16 and 17, the light emitting element LE may include a conductive layer E1, a semiconductor stack STC, contact electrodes CTE1 and CTE2, a first reflective layer RF1, and a protective film INS. The semiconductor stack STC may include a third semiconductor layer SEM3, a second semiconductor layer SEM2, an active layer MQW, and a first semiconductor layer SEM1 sequentially disposed and/or stacked along the third direction DR3.

The pin pad FPD may include a conductive layer E1, a semiconductor stack STC, a contact pad CPD, and a protective film INS.

The conductive layer E1 may be disposed on the semiconductor stack STC. In FIG. 17, the conductive layer E1 is illustrated covering the entire underside of the first semiconductor layer SEM1, but the present disclosure is not limited thereto. In one example, the conductive layer E1 may be disposed on a portion of the lower surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu). In addition, the conductive layer E1 may be made of a transparent conductive material (TCO), such as indium tin oxide (ITO) and/or indium zinc oxide (IZO), which can transmit light.

The semiconductor stack STC of the pin pad FPD may be formed in the same process as the semiconductor stack STC of the light emitting element LE. Accordingly, the pin pad FPD may include the semiconductor stack STC having the same structure as the semiconductor stack STC of the light emitting element LE. For example, the semiconductor stack STC of the pin pad FPD may include a third semiconductor layer SEM3, a second semiconductor layer SEM2, an active layer MQW, and a first semiconductor layer SEM1 sequentially disposed and/or stacked along the third direction DR3.

The third semiconductor layer SEM3 is a semiconductor material layer in which the n-type dopant is lower than a suitable threshold value (e.g., a predetermined threshold value) and may be referred to as an un-doped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) in which the n-type dopant is lower than a suitable threshold (e.g., a predetermined threshold).

The second semiconductor layer SEM2 may be a semiconductor material layer doped with a second conductivity type dopant such as silicon (Si), germanium (Ge), tin (Sn), and/or the like, for example, gallium nitride (GaN).

The active layer MQW may include the same semiconductor material layer as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light by combining electron-hole pairs according to an electrical signal applied through the first semiconductor layer SEM1 and the second semiconductor layer SEM2.

The length of the bottom surface of the first semiconductor layer SEM1 in the first direction DR1 and/or the length in the second direction DR2 may be smaller than the length of the contact electrode CTE in the first direction DR1 or the length in the second direction DR2. The first semiconductor layer SEM1 may include a semiconductor material layer doped with a first conductive dopant, such as magnesium (Mg), zinc (Zn), calcium (Ca), strontium (Sr), barium (Ba), and/or the like, for example gallium nitride (GaN).

The protective film INS may be disposed on a side of the conductive layer E1, a side of the first semiconductor layer SEM1, a side of the active layer MQW, a side of the second semiconductor layer SEM2, and a side of the third semiconductor layer SEM3. The protective film INS may extend from the protective film INS of the light emitting element LE. The protective film INS may be formed of an inorganic film, such as silicon nitride (SiNx), silicon oxide (SiON), silicon oxide (SiOx), titanium oxide (TiOx), and/or aluminum oxide (AlOx).

The contact pad CPD may be disposed on the protective film INS and may extend from either the first contact electrode CTE1 or the second contact electrode CTE2 of the light emitting element LE.

The contact pad CPD may be formed in the same process as the first contact electrode CTE1 and the second contact electrode CTE2 of the light emitting element LE.

The contact pad CPD may include a metal, metal oxide, and/or other conductive material that has a higher conductivity than the first reflective layer RF1 of the light emitting element LE. For example, the first contact electrode CTE1 and the second contact electrode CTE2 may include gold (Au), copper (Cu), and/or chromium (Cr).

In this way, the pin pad FPD has a semiconductor stack STC of the same height in the same process as the light emitting element LE. Because of this, contact between the test pin and the pin pad FPD may be facilitated in the test process.

On the other hand, because the connector CNT does not have a semiconductor stack STC and may be disposed lower than the height of the pin pad FPD and the light emitting element LE.

As shown in FIGS. 16 and 17, one light emitting element LE and two pin pads FPD1 and FPD2 connected to each contact electrode CTE1 and CTE2 of the light emitting element LE may be referred to as one test block TB. Independent electrical tests may be performed for each test block TB. The first pin pad FPD1 and the second pin pad FPD2 connected to one light emitting element LE may be electrodes of different polarities.

Because the pin pads FPD, the contact electrodes CTE1 and CTE2, and the connectors CNT1 and CNT2 are formed in the same process, they may include the same material. For example, the pin pads FPD, the contact electrodes CTE1 and CTE2, and the connectors CNT1 and CNT2 may include molybdenum (Mo), aluminum (Al), chromium (Cr), gold (Au), titanium (Ti), nickel (Ni), neodymium (Nd), and/or copper (Cu).

The width of the connectors CNT1 and CNT2 may be narrower than the width of the light emitting element LE.

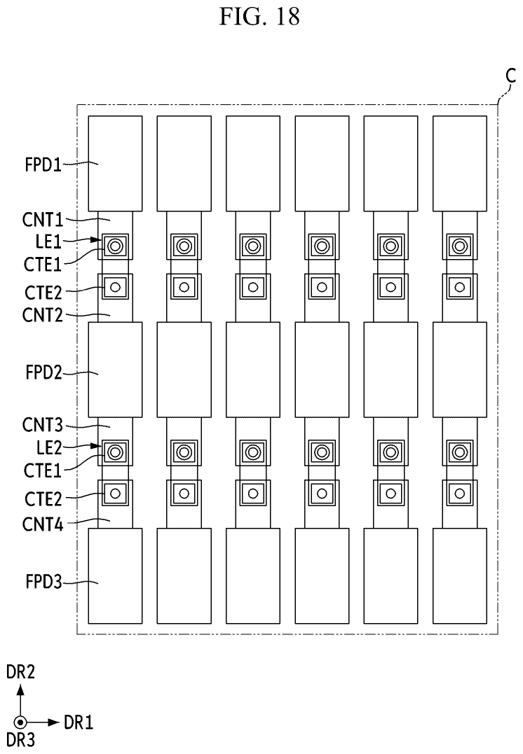

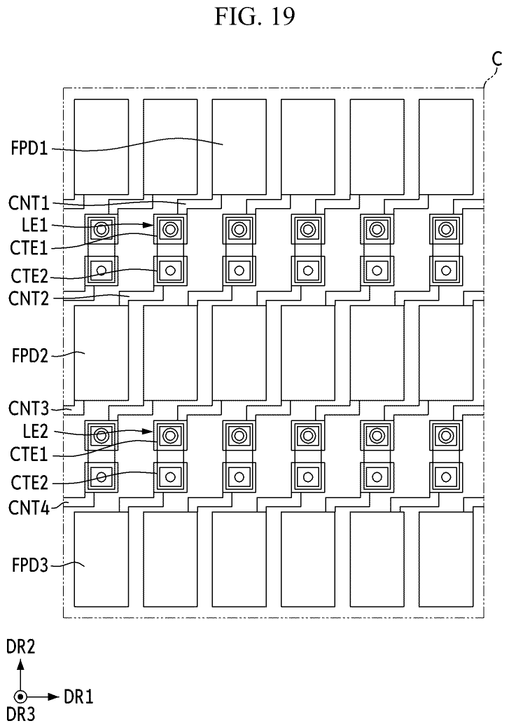

FIGS. 18 and 19 are layout views illustrating one example of the area C in FIG. 14 in detail according to one or more other embodiments.

Referring to FIG. 18, it differs from the embodiment of FIG. 15 in that the width of the connectors CNT1 and CNT2 is the same as or wider than the width of the light emitting element LE. In the embodiments of FIGS. 18 and 19, descriptions overlapping with the embodiment of FIG. 15 will be omitted.

For example, the width of the connectors CNT1 and CNT2 may be the same as the width of the contact electrodes CTE1 and CTE2. If the width of the connectors CNT1 and CNT2 is formed to be equal to or wider than the width of the light emitting element LE, it may be an advantage in that the possibility of short circuit of the connectors CNT1 and CNT2 is reduced.

Referring to FIG. 19, it is different from the embodiment of FIG. 15 in that the first pin pad FPD1 and the second pin pad FPD2 connected to one light emitting element LE are not disposed in a straight line in the first direction. The first pin pad FPD1 and the second pin pad FPD2 are not disposed in a straight line with the light emitting element LE in the first direction.

The first light emitting element LE1 and the second light emitting element LE2 are arranged in the first direction, and the first pin pad FPD1 connected to the first contact electrode CTE1 of the first light emitting element LE1 is not disposed in a line with the first light emitting element LE1 in the first direction, and the second pin pad FPD2 connected to the second contact electrode CTE2 of the first light emitting element LE1 is not disposed in a line with the first light emitting element LE1 in the first direction.

In this way, the two pin pads included in one test block TB are not disposed in the same straight line with the light emitting element LE in the first direction but may be disposed offset (e.g., offset from each other). When two pin pads are arranged so that the light emitting elements (LE) are misaligned, there is an advantage in that the possibility of contact between test probes can be reduced due to the thickness of the probe during testing.

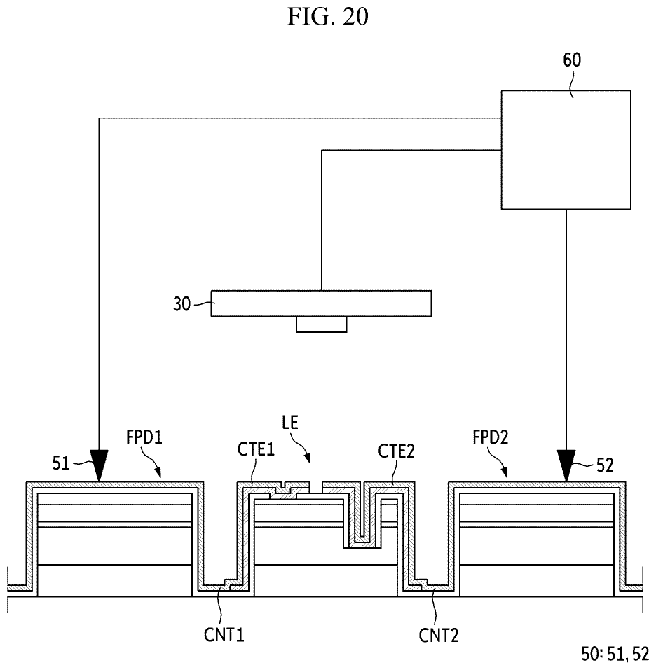

FIG. 20 is a schematic diagram illustrating a light emitting element inspection device according to one or more embodiments. The wafer of FIG. 20 may be the same as the wafer EWF described with reference to FIGS. 14-19.

The light emitting element inspection device may include a wafer EWF having a pin pad FPD and a light emitting element LE, a power application portion 50, an image sensor 30, and a control portion 60.

The power application portion 50 includes a plurality of probes 51 and 52 and applies test supply power to the light emitting element LE to be inspected using the plurality of probes 51 and 52.

For example, after contacting the first probe 51 with the first pin pad FPD1 connected to the first contact electrode CTE1 of the light emitting element LE, and the second probe 52 with the second pin pad FPD2 connected to the second contact electrode CTE2 of the light emitting element LE, the power application part 50 applies test supply power to the plurality of light emitting elements LE through the first probe 51 and the second probe 52. The power application portion 50 may be driven by an externally applied signal, and when the supply power is applied, the test supply power is applied to the plurality of light emitting elements LE to be inspected to check whether the plurality of light emitting elements LE are defective. A normal light emitting element LE may illuminate when test supply power is applied.

One or more image sensors 30 are disposed on one side of the light emitting elements to acquire images of light emitted from the light emitting elements. The image sensor 30 may be, for example, a camera. Here, the camera may include, but is not limited to, an area scan camera or a line scan camera, and any device that is capable of photographing objects other than a camera may be used.

The control portion 60 may be electrically connected to the image sensor 30 and the power application portion 50 to transmit and receive information. The control portion 60 may control the operation of the image sensor 30 and the power application portion 50. The information transmitted and received by the control portion 60 may include, for example, a reference image for determining a defect in a light emitting element. The reference image may be stored in the control portion 60 prior to inspection. The control portion 60 may determine lighting defects through the image acquired through the image sensor 30.

For example, the control portion 60 may determine the defect of the light emitting element by comparing at least one of luminance and illuminance in the acquired image to a preset reference. For example, if any light emitting element in the acquired image has a significantly lower at least one of luminance or illuminance compared to other light emitting elements, the light emitting element may be determined to be defective.

In one or more embodiments, when a malfunction is detected in some light emitting elements LE, a process for removing the corresponding light emitting elements LE may be performed separately.

According to one or more embodiments, the light emitting elements LE on the wafer (EWF) may be inspected for defects.

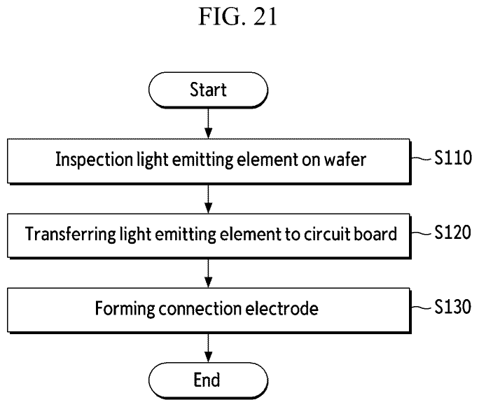

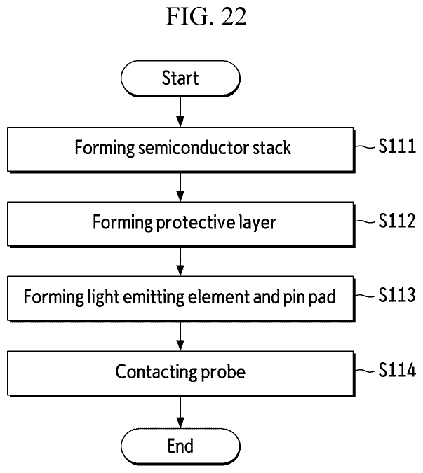

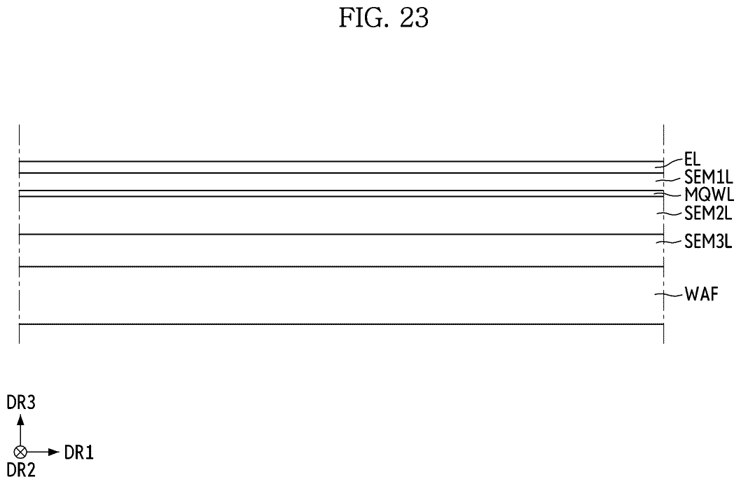

FIG. 21 is a flowchart illustrating a method of manufacturing a display device according to one or more embodiments. FIG. 22 is a flowchart illustrating a method of manufacturing another wafer according to one or more embodiments. FIGS. 23-30 are diagrams for illustrating a method of manufacturing a wafer and a method of transferring a light emitting element according to one or more embodiments.

The method of manufacturing a wafer described with reference to FIG. 22 is a flowchart for explaining in detail the method of inspection a light emitting element on a wafer described with reference to FIG. 21. The wafers referred to with reference to FIGS. 21-30 may be the wafers described with reference to FIGS. 14-19. The light emitting element inspection device referred to with reference to FIGS. 21-30 may be the light emitting element inspection device described with reference to FIG. 20.

To manufacture a display device, the light emitting element on the wafer may first be inspected. (e.g., S110 in FIG. 20)

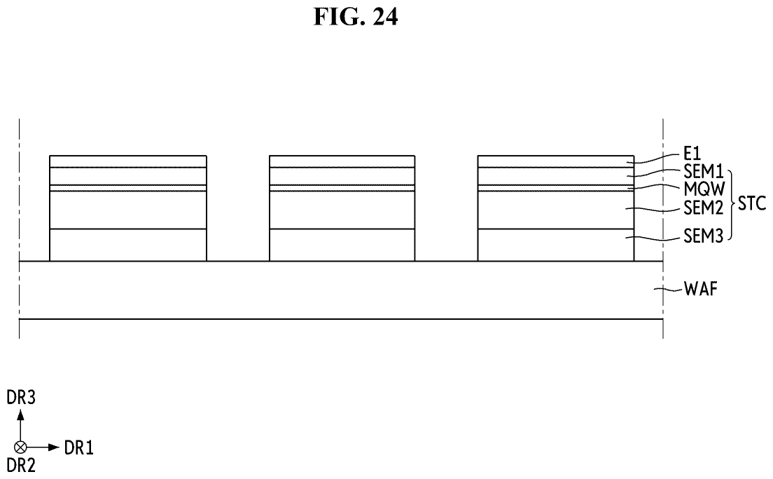

For example, referring to FIGS. 23 and 24, a semiconductor stack STC is formed on a wafer substrate WAF. (e.g., S111 in FIG. 22)

First, the wafer substrate WAF is prepared. The wafer substrate WAF may be a sapphire substrate Al₂O₃ and/or a silicon wafer including silicon. However, it is not limited thereto, and in one or more embodiments, a case where the wafer substrate WAF is a sapphire substrate will be described as an example.

A plurality of semiconductor material layers are formed on a wafer substrate WAF. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group such as a methyl and/or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

A third semiconductor material layer SEM3L is formed on the wafer substrate WAF. In the drawing, the third semiconductor material layer SEM3L is shown as one more layer, but the present disclosure is not limited this, and multiple layers may be formed. The third semiconductor material layer SEM3L may be disposed to reduce the difference in lattice constant between the second semiconductor material layer SEM2L and the wafer substrate WAF. In one example, the third semiconductor material layer SEM3L may include an undoped semiconductor and may be a material that is not doped as n-type or p-type. In one or more embodiments, the third semiconductor material layer SEM3L may be undoped InAlGaN, GaN, AlGaN, InGaN, AlN, and/or InN but is not limited thereto.

The second semiconductor material layer SEM2L, the active material layer MQWL, and the first semiconductor material layer SEM1L are sequentially formed on the third semiconductor material layer SEM3L using the above-described method. In another modified example, a superlattice material layer may be formed between the second semiconductor material layer SEM2L and the active material layer MQWL. Furthermore, an electron blocking material layer may be formed between the active material layer MQWL and the first semiconductor material layer SEM1L.

A conductive material layer EL may be further formed on the semiconductor stack STC. The conductive material layer EL may include molybdenum (Mo), aluminum (Al), chromium (Cr), gold (Au), titanium (Ti), nickel (Ni), neodymium (Nd), and/or copper (Cu), and/or may be made of a transparent conductive material (TCO), such as indium tin oxide (ITO) and/or indium zinc oxide (IZO), that is capable of transmitting light.

Next, referring to FIG. 24, a semiconductor stack STC is formed by mesa-etching a plurality of semiconductor material layers through an etching process using a mask.

Specifically, a mask pattern is formed on the conductive layer E1. The mask pattern may be a hard mask containing an inorganic material and/or a photoresist mask including an organic material. The mask pattern prevents the underlying plurality of semiconductor material layers from being etched. Then, a portion of the plurality of semiconductor material layers is etched using the plurality of mask patterns as masks to form a plurality of semiconductor stacks STC.

The semiconductor material layers may be etched by conventional methods. For example, the process for etching semiconductor material layers may be dry etching, wet etching, reactive ion etching (RIE), deep reactive ion etching (DRIE), inductively coupled plasma reactive ion etching (ICP-RIE), and/or the like. In the case of dry etching, anisotropic etching is possible and may be suitable for vertical etching. When using the etching method described above, the etching etchant may be Cl₂ and/or O₂. However, it is not limited to this.

The plurality of semiconductor material layers overlapping the mask pattern are not etched but formed into a semiconductor stack STC. Accordingly, the semiconductor stack STC is formed including the third semiconductor layer SEM3, the second semiconductor layer SEM2, the active layer MQW, and the first semiconductor layer SEM1.

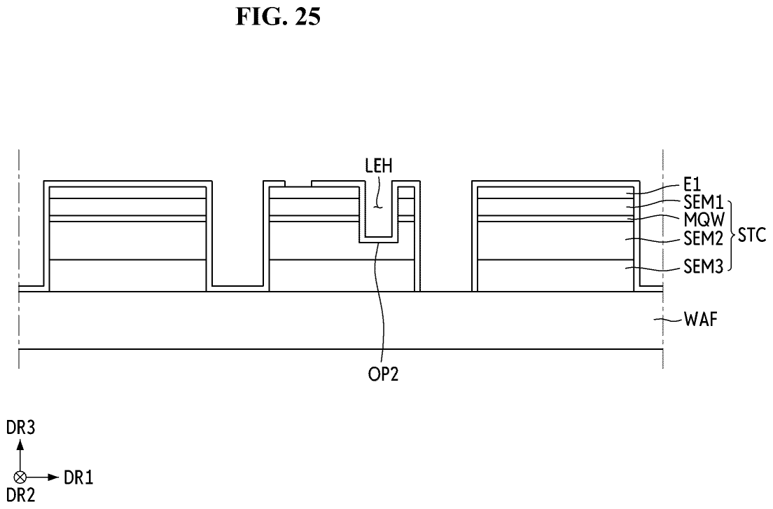

Referring to FIG. 25, a protective layer INS is formed on the wafer WAF on which the semiconductor stack STC is formed (e.g., S112 in FIG. 22).

For example, as shown in FIG. 25, a portion of the semiconductor stack STC is etched to form a hole LEH. For example, the hole LEH is formed in the semiconductor stack STC, and the hole LEH is not formed in the third semiconductor layer SEM3. The hole LEH penetrates the conductive layer E1, the first semiconductor layer SEM1, and the active layer MQW, and exposes the second semiconductor layer SEM2.

The hole LEH may be formed only on the semiconductor stack STC for the light emitting element LE.

For example, a protective material layer is applied entirely to the wafer substrate WAF. The protective material layer may be disposed on the top and side surfaces of the semiconductor stack STC.

Next, etching is performed to partially remove the protective material layer of the semiconductor stack STC to form a protective layer INS having a first opening OP1 and a second opening OP2 on the top surface of the semiconductor stack STC for the light emitting element LE. For example, the openings OP1 and OP2 may be formed in the semiconductor stack STC for the light emitting element LE, and the openings OP1 and OP2 may not be formed in the semiconductor stack STC for the pin pads FPD. The first opening OP1 and the second opening OP2 are formed to be spaced (e.g., spaced apart), and the second opening OP2 may be located in the center of the hole LEH. In this process, a portion of the protective material layer may be removed from the top surface of the conductive layer E1. Additionally, a portion of the protective material layer may be removed from the bottom of the hole LEH to expose the second semiconductor layer SEM2. The process of partially removing the protective material layer may be performed through an anisotropic dry etching followed by an etch-back process but is not limited to this.

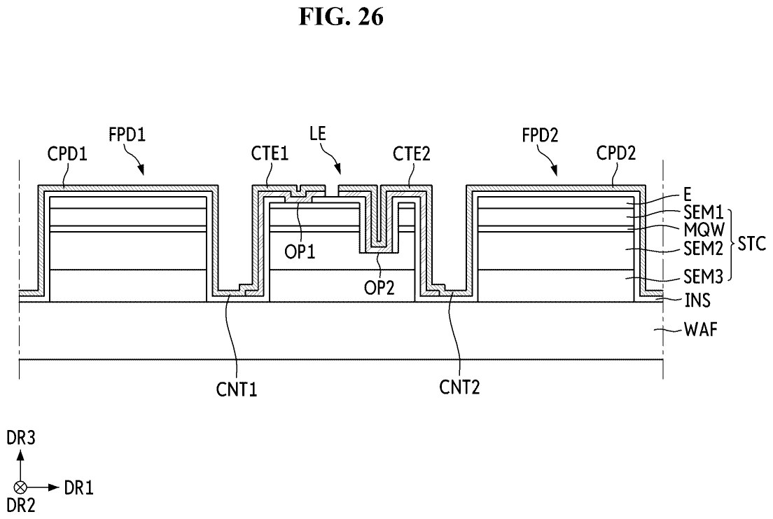

Next, referring to FIG. 26, a light emitting element LE, a pin pad FPD, and a connector CNT are formed. (e.g., S113 in FIG. 22)

First, a first reflective layer RF1 may be formed on the protective layer INS of the semiconductor stack STC. For example, a first reflective material layer is formed on the semiconductor stack STC for the light emitting element LE and, but the first reflective material layer is not formed on the semiconductor stack STC for the pin pad FPD. The first reflective material layer may be deposited through a process such as sputtering but is not limited thereto.

The first reflective layer RF1 may be formed by etching a portion of the first reflective material layer using a photo process.

The photo process is a process for forming a desired structure by applying photoresist (PR) on a substrate and then passing light through a mask with a desired pattern. In this way, photo process tolerances may occur due to the mask and light passing through the photo process. For example, a photoresist may be formed on the semiconductor layer stack. When forming the first reflective layer RF1 using the first photoresist as a mask, a portion protrudes outward from the bottom of the semiconductor stack due to photo process tolerance. The photo process tolerance may vary depending on photographic equipment but may be about 0.5 μm to 2 μm. Accordingly, the protrusion length of the first reflective layer RF1 may be formed within a range of 0.6 μm to 2.4 μm, including a margin of about 20% in the photo process tolerance.

Next, the contact electrodes CTE1 and CTE2 or contact pads CPD are formed. For example, the contact electrodes CTE1 and CTE2 are formed on the first reflective layer RF1 in the semiconductor stack STC for the light emitting element LE and the contact pads CPD are formed in the semiconductor stack STC for the pin pads FPD.

For example, a conductive material layer is formed on the entire surface of a wafer substrate WAF including a plurality of semiconductor layer stacks STC. The conductive material layer may be deposited through a process such as sputtering but is not limited to this.

By forming a conductive material layer on the entire surface of the wafer substrate WAF, contact electrodes CTE1 and CTE2 or contact pads CPD may be formed on the semiconductor stack STC, and connectors CNT may be formed on the wafer substrate WAF without the semiconductor stack STC disposed thereon.

The contact electrodes CTE1 and CTE2 may be formed by etching a portion of the conductive material layer using a photo process.

Thereafter, the photoresist remaining on the wafer substrate WAF may be removed by stripping or ashing.

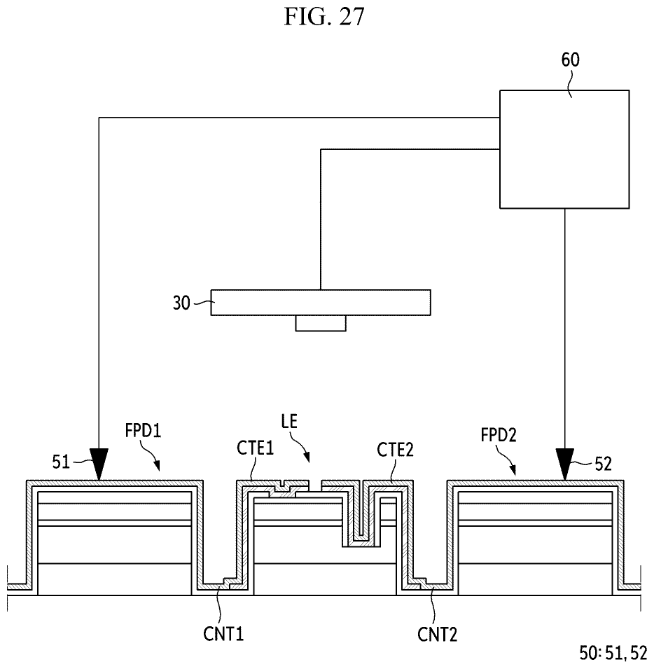

Next, referring to FIG. 27, the light emitting element LE may be inspected by contacting the probe (e.g., S114, FIG. 22).

After contacting the first probe 51 to the first pin pad FPD1 associated with the first contact electrode CTE1 of the light emitting element LE, and the second probe 52 to the second pin pad FPD2 associated with the second contact electrode CTE2 of the light emitting element LE, test supply power may be applied.

The test supply power may be applied to the light emitting elements LE through the power application portion 50 to check whether the plurality of light emitting elements are defective.

The image sensor 30 acquires an image of light emitted from the light emitting element LE to which test supply power is applied. The acquired image may be transmitted to the control portion 60.

The control portion 60 may determine the characteristics of the light emitting element by comparing the image with a suitable (e.g., pre-stored) reference image.

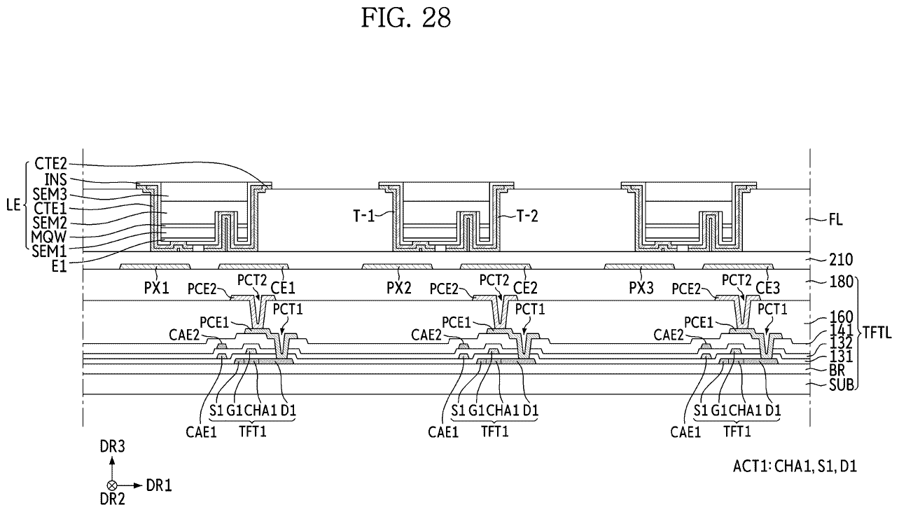

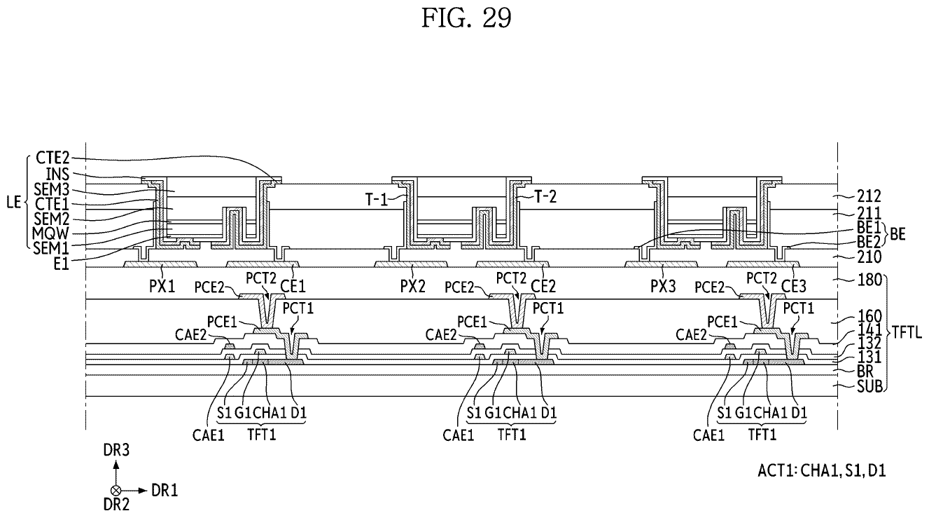

Referring to FIGS. 28 and 29, the light emitting element LE on the wafer EWF, which is determined to be a good product by the control portion 60, is transferred to the circuit board substrate SUB. (e.g., S120 in FIG. 21)

For example, an insulating film FL disposed between the light emitting elements LE is formed, the light emitting elements LE are transferred to the first organic film 210 disposed on the pixel electrodes PXE, and the wafer substrate WAF is removed.

An insulating film FL may be formed between the light emitting elements LE in order to prevent the light emitting elements LE from being separated from or moving from the wafer substrate WAF due to external shock during the transfer process. The insulating film FL may be formed of an organic film and/or an inorganic film.

Although FIG. 28 illustrates that the insulating film FL fills all of the space between the light emitting elements LE, the present disclosure is not limited thereto. In one example, the insulating film FL may fill a portion of the space between the light emitting elements LE.

The light emitting elements LE may be transferred onto the first organic film 210 disposed on the pixel electrodes PXE. At this time, the light emitting elements LE may be embedded in the first organic film 210 and temporarily fixed thereto. FIG. 28 illustrates that the first contact electrode CTE1 and the second contact electrode CTE2 of each of the light emitting elements LE are disposed on the first organic film 210, but the present disclosure is not limited to this. For example, the first organic film 210 may be disposed on a portion of the bottom surface and side surface of the first contact electrode CTE1 and a portion of the bottom surface and side surface of the second contact electrode CTE2 of each of the light emitting elements LE. Alternatively, the first organic film 210 may be disposed on the side surfaces of the conductive layer E1 of each of the light emitting elements LE. Alternatively, the first organic film 210 may be disposed on a side of the first semiconductor layer SEM1, a side of the active layer MQW, and a side of the second semiconductor layer SEM2 of each of the light emitting elements LE. In this case, the first organic film 210 may be disposed on a portion of each side of the second semiconductor layer SEM2.

When the fluidity of the first organic film 210 is small or the first organic film 210 is hard, the depth at which the light emitting element LE is inserted or embedded in the first organic film 210 may be very small, or the light emitting element LE may be placed on the first organic film 210 without being inserted or embedded in the first organic film 210.

When the first organic film 210 is a photosensitive organic film such as a photoresist, the first organic film 210 can be soft baked at a first temperature, and then at least a portion of each of the plurality of light emitting elements LE may be inserted into the first organic film 210. Then, the first organic film 210 may be completely cured at a second temperature higher than the first temperature. The first temperature may be approximately 100 degrees, and the second temperature may be approximately 230 degrees, but the present disclosure is not limited thereto. Furthermore, the process of completely curing the first organic film 210 at the second temperature may be performed for approximately 30 minutes.

Then, the wafer substrate WAF is removed using a laser lift-off process. When the laser lift-off process separates the light emitting element LE and the wafer substrate WAF, a laser is applied to the connector CNT portion of the light emitting element LE on the wafer WAF, so that the light emitting element LE may have a tip.

Alternatively, when the light emitting elements LE are transferred and transferred to a separate transfer substrate rather than the wafer substrate WAF, the transfer substrate may be removed instead of the wafer substrate WAF. In another modification, a mask may be formed on the light emitting element (LE in FIG. 15), a pin pad area may be etched, and then the light emitting element LE may be transferred.

As shown in FIG. 29, the insulating film FL is removed, the first connection electrodes BE1 and the second connection electrodes BE2 are formed, and the second organic film 211 and the third organic film 212 are formed. (e.g., S130 in FIG. 21)

The insulating film FL may be removed using a chemical solution. The insulating film FL may be an organic film and/or an inorganic film, and the chemical solution may be hydrochloric acid (HCl) and tetramethylammonium hydroxide (TMAH), but the present disclosure is not limited thereto.

When the first contact electrode CTE1 and the second contact electrode CTE2 are arranged to cover the entire side surface of the semiconductor stack STC, the first contact electrode CTE1 and the second contact electrode CTE1 exposed on the top surface of the semiconductor stack STC may be exposed to the chemical solution. The chemical solution may penetrate between the first contact electrode CTE1 and the protective film INS and between the second contact electrode CTE2 and the protective film INS, thereby causing the first contact electrode CTE1 and the second contact electrode CTE2 to peel away from the insulating film INS.

However, in one or more embodiments of the present disclosure, each of the first contact electrode CTE1 and the second contact electrode CTE2 is spaced (e.g., spaced apart) from the top surface of the semiconductor stack STC, so that the first contact electrode CTE1 and the second contact electrode CTE2 are protected by the insulating film FL and are not exposed to the chemical solution. Therefore, the first contact electrode CTE1 and the second contact electrode CTE2 may be prevented from being peeled off by the drug solution.

Then, the first connection electrodes BE1 for connecting the first contact electrode CTE1 and the pixel electrode PXE of the light emitting element LE disposed on the first organic film 210 and the second connection electrodes BE2 for connecting the second contact electrode CTE2 and the common electrode CE are formed.

Then, the third organic layer 211 and the fourth organic layer 212 are formed to fix the light emitting elements LE and to flatten the steps caused by the light emitting elements LE.

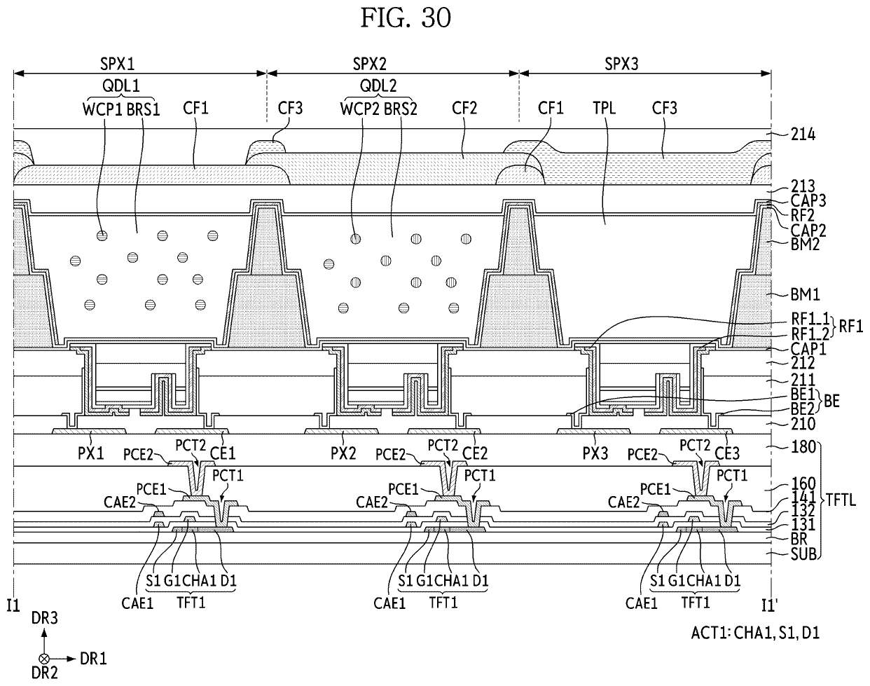

As shown in FIG. 30, a light blocking layer, a wavelength conversion layer, a light transmission layer, and a color filter layer are sequentially formed.

A first capping layer CAP1 is formed on the fourth organic film 212 and the light emitting elements LE, and a first light blocking layer BM1 and a second light blocking layer BM2 are formed on the first capping layer CAP1 so as not to overlap with the light emitting elements LE in the third direction DR3. Then, a second capping layer CAP2 is formed to cover the first light blocking layer BM1, the second light blocking layer BM2, and the first capping layer CPL1. Then, a second reflective layer RF2 is formed to cover the second capping layer CAP2 disposed on the first light blocking layer BM1 and the second light blocking layer BM2.

Then, a first light conversion layer QDL1 is formed in each of the first sub-pixels SPX1, a second light conversion layer QDL2 is formed in each of the second sub-pixels SPX2, and a light transmission layer TPL is formed in each of the third sub-pixels SPX3. Then, a third capping layer CAP3 is formed to cover the first light conversion layers QDL1, the second light conversion layers QDL2, and the light transmission layer TPL. Then, a fifth organic film 213 is formed on the third capping layer CAP3.

Then, a first color filter CF1 is formed that overlaps the first light conversion layers QDL1 in the third direction DR3, a second color filter CF2 is formed that overlaps the second light conversion layer QDL2 in the third direction DR3, and a third color filter CF3 is formed that overlaps the light transmission layer TPL in the third direction DR3 on the fifth organic film 213. In an area overlapping the first light blocking layer BM1 and the second light blocking layer BM2 in the third direction DR3, the first color filter CF1, the second color filter CF2, and the third color filter CF3 may all be formed.

Then, a sixth organic film 214 is formed on the first color filter CF1, the second color filter CF2, and the third color filter CF3.

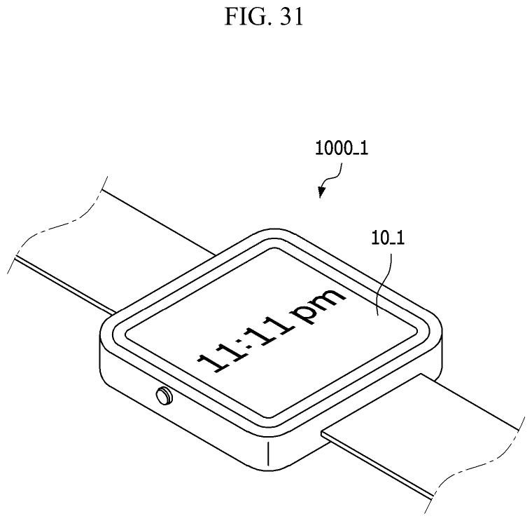

FIG. 31 is an example view of a smart watch including a display device according to one or more embodiments.

Referring to FIG. 31, a display device 10_1 according to one or more embodiments may be applied to a smart watch 1000_1 which is one of smart devices.

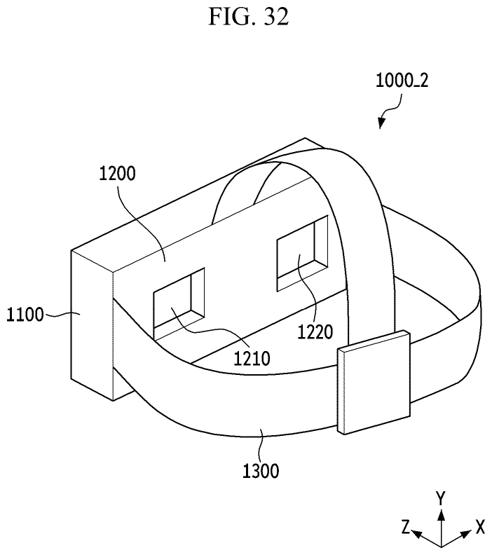

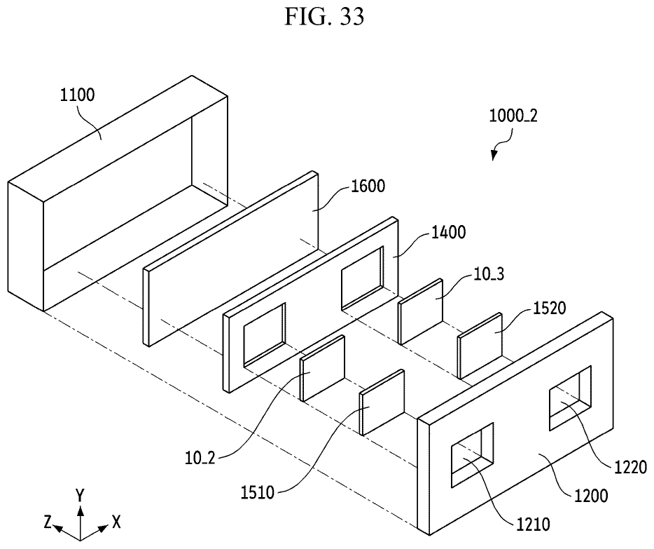

FIGS. 32 and 33 are example views of a virtual reality (VR) device including a display device according to one or more embodiments.

Referring to FIGS. 32 and 33, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

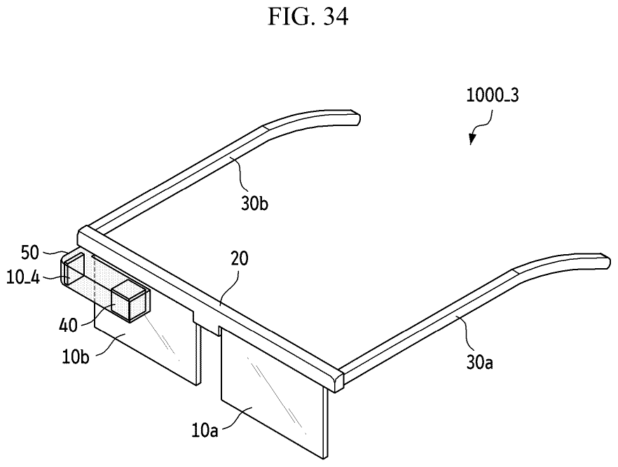

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 33 and 34, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 33 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 34 is an example view of a VR device including a display device according to one or more embodiments. FIG. 34 illustrates a VR device 1000_3 to which a display device 10_4 according to one or more embodiments has been applied.

Referring to FIG. 34, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

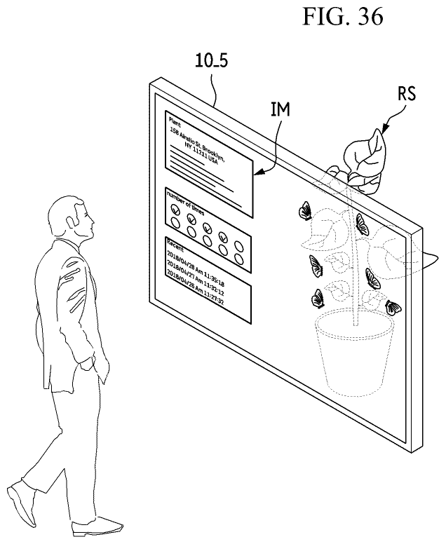

In FIG. 34, a case where the VR device 1000_3 is a glasses-type display device including the eyeglass frame legs 30a and 30b is illustrated as an example. That is, the VR device 1000_3 according to the embodiment is not limited to the one illustrated in FIG. 36 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 34, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

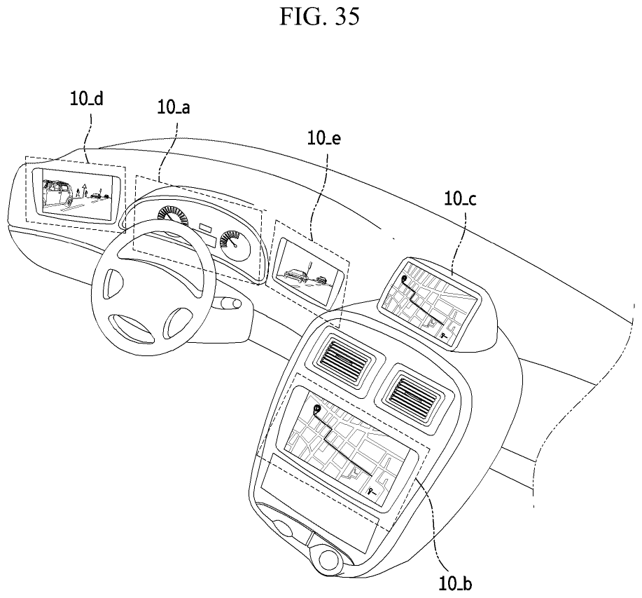

FIG. 35 is an example view illustrating a vehicle instrument cluster and center fascia including display devices according to one or more embodiments. FIG. 35 illustrates a vehicle to which display devices 10_a through 10_e according to one or more embodiments have been applied.

Referring to FIG. 35, the display devices 10_a through 10_c according to the embodiment may be applied to an instrument cluster of the vehicle, a center fascia of the vehicle, and/or a center information display (CID) disposed on a dashboard of the vehicle. In addition, the display devices 10_d and 10_e according to the embodiment may be applied to room mirror displays that replace side mirrors of the vehicle.

FIG. 36 is an example view of a transparent display device including a display device according to one or more embodiments.

Referring to FIG. 36, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the principles and scopes of the present disclosure. Therefore, the embodiments of the present disclosure are used in a generic and descriptive sense only and not for purposes of limitation

What is claimed is:

1. A wafer comprising:
a substrate;
a plurality of light emitting elements on the substrate, each of the plurality of light emitting elements comprising a semiconductor stack, a first contact electrode, and a second contact electrode;
a plurality of pin pads on the substrate and comprising a semiconductor stack; and
a plurality of connectors connecting different pin pads to each of the first contact electrode and the second contact electrode of a light emitting element from among the plurality of light emitting elements.

2. The wafer of claim 1, wherein the semiconductor stack comprises a third semiconductor layer, a second semiconductor layer, an active layer, and a first semiconductor layer sequentially stacked.

3. The wafer of claim 1, wherein the plurality of pin pads comprises a first pin pad and a second pin pad,
wherein a connector from among the plurality of connectors comprises a first connector connecting the first contact electrode and the first pin pad and a second connector connecting the second contact electrode and the second pin pad.

4. The wafer of claim 3, wherein the first pin pad, the light emitting element, and the second pin pad are aligned with each other in a first direction.

5. The wafer of claim 3, wherein the first pin pad and the second pin pad are not aligned in a first direction, and the light emitting element is not aligned with the first pin pad and the second pin pad.

6. The wafer of claim 1, wherein the plurality of pin pads further comprises a contact pad on the semiconductor stack,
wherein the contact pad, the first contact electrode, the second contact electrode, and the plurality of connectors are formed integrally with each other.

7. The wafer of claim 1, wherein the plurality of light emitting elements is arranged along a first direction and a second direction,
wherein the plurality of pin pads is arranged alternately with the plurality of light emitting elements along the second direction,
wherein a pin pad located between a first light emitting element and a second light emitting element in the second direction is connected to the second contact electrode of the first light emitting element and is connected to the first contact electrode of the second light emitting element.

8. The wafer of claim 7, wherein the semiconductor stack of the light emitting element includes a concave groove exposing a second semiconductor layer of the semiconductor stack in an area overlapping the second contact electrode,
wherein the second contact electrode is electrically connected to the second semiconductor layer exposed by the concave groove, and
wherein the first contact electrode is electrically connected to a first semiconductor layer of the semiconductor stack.

9. A display device comprising:
a substrate;
a pixel electrode and a common electrode on the substrate and spaced from each other;
a light emitting element on the pixel electrode and the common electrode;
a first contact electrode on the light emitting element and the pixel electrode, and a second contact electrode on the light emitting element and the common electrode; and
wherein the light emitting element comprises:
a semiconductor layer stack;
a protective layer around all sides of the semiconductor layer stack except one side;
a reflective layer around the semiconductor layer stack on the protective layer;
a first tip extending from the first contact electrode and protruding outward perpendicular to a side surface of the semiconductor layer stack; and
a second tip extending from the second contact electrode and protruding outward perpendicular to a side surface of the semiconductor layer stack.

10. The display device of claim 9, further comprising a first connection electrode electrically connecting the first contact electrode and the pixel electrode, and a second connection electrode electrically connecting the second contact electrode and the common electrode.

11. The display device of claim 9, wherein the reflective layer further comprises a first reflective layer between the first contact electrode and the protective layer and a second reflective layer between the second contact electrode and the protective layer, and
wherein the first reflective layer and the second reflective layer are electrically short-circuited.

12. The display device of claim 9, wherein the semiconductor layer stack includes a concave groove exposing a second semiconductor layer of the semiconductor layer stack in an area overlapping the second contact electrode,
wherein the second contact electrode is electrically connected to the second semiconductor layer exposed by the concave groove, and
wherein the first contact electrode is electrically connected to a first semiconductor layer of the semiconductor layer stack.

13. An inspection method of light emitting element, the method comprising:
forming a plurality of semiconductor stacks by stacking and etching a plurality of semiconductor material layers stacked on a substrate;
forming a protective layer covering a portion of top and side surfaces of the plurality of semiconductor stacks;
forming a contact electrode or a contact pad on the protective layer to form a light emitting element or a pin pad, wherein the pin pad is electrically connected to the contact electrode through a connector; and
contacting a first probe and a second probe to each of a first pin pad and a second pin pad of the pin pad connected to the contact electrode of the light emitting element and applying test supply power.

14. The method of claim 13, wherein in the forming the contact electrode or the contact pad on the protective layer to form the light emitting element or the pin pad, the pin pad is electrically connected to the contact electrode through the connector,
wherein the light emitting element is formed by forming a first contact electrode and a second contact electrode on the protective layer of a first semiconductor stack of the plurality of semiconductor stacks,
wherein the first pin pad is formed by forming the contact pad on the protective layer of a second semiconductor stack of the plurality of semiconductor stacks;
wherein the second pin pad is formed by forming the contact pad on the protective layer of a third semiconductor stack of the plurality of semiconductor stacks,
wherein the connector comprises a first connector and a second connector, wherein the method further comprises forming the first connector connecting the first contact electrode and the first pin pad and the second connector connecting the first contact electrode and the second pin pad.

15. The method of claim 14, wherein the first semiconductor stack, the second semiconductor stack, and the third semiconductor stack are arranged with each other along a straight line in a first direction.

16. The method of claim 14, further comprising acquiring an image of light emitted from the light emitting element to which the test supply power is applied; and
determining characteristics of the light emitting element by a control portion comparing the acquired image with a reference image.

17. A manufacturing method of a display device comprising a plurality of light emitting elements, the method comprising:
forming a plurality of semiconductor stacks by stacking and etching a plurality of semiconductor material layers stacked on a wafer substrate;
forming a protective layer covering a portion of top and side surfaces of the plurality of semiconductor stacks;
forming a contact electrode or a contact pad on the protective layer to form a light emitting element of the plurality of light emitting elements or a pin pad, wherein the pin pad is electrically connected to the contact electrode through a connector;
contacting a first probe and a second probe to each of a first pin pad and a second pin pad of the pin pad connected to the contact electrode of the light emitting element and inspecting the light emitting element; and
transferring the plurality of light emitting elements to a circuit board.

18. The method of claim 17, wherein in the forming the contact electrode or the contact pad on the protective layer to form the light emitting element or the pin pad, the pin pad is electrically connected to the contact electrode through the connector comprising a first connector and a second connector, the contact electrode comprising a first contact electrode and a second contact electrode,
wherein the light emitting element is formed by forming the first contact electrode and the second contact electrode on the protective layer of a first semiconductor stack of the plurality of semiconductor stacks,
wherein the first pin pad is formed by forming the contact pad on the protective layer of a second semiconductor stack of the plurality of semiconductor stacks,
wherein the second pin pad is formed by forming the contact pad on the protective layer of a third semiconductor stack of the plurality of semiconductor stacks,
wherein the first connector connecting the first contact electrode and the first pin pad, and the second connector connecting the first contact electrode and the second pin pad.

19. The method of claim 17, wherein the contacting the first probe and the second probe to each of the first pin pad and the second pin pad connected to the contact electrode of the light emitting element and inspecting the light emitting element comprises:
contacting the first probe and the second probe to each of the first pin pad and the second pin pad connected to the contact electrode of the light emitting element and applying test supply power;
acquiring an image of light emitted from the light emitting element to which the test supply power is applied; and
determining characteristics of the light emitting element by a control portion comparing the acquired image with a reference image.

20. The method of claim 17, wherein the circuit board includes a plurality of pixel circuit portions, a pixel electrode connected to each of the pixel circuit portion, and a common electrode spaced from the pixel electrode,
wherein the light emitting element comprises a first contact electrode and a second contact electrode,
wherein after the plurality of light emitting elements is transferred to the circuit board, the method further comprises:
forming a first connection electrode connecting the first contact electrode and the pixel electrode and a second connection electrode connecting the second contact electrode and the common electrode.
